(19) United States
(12) Patent Application Publication
(10) Pub. No.: US 2026/0333844 A1
(43) Pub. Date: Oct. 22, 2026

(54) SEMICONDUCTOR DEVICE WITH CAPACITOR AND METHOD FOR FORMING THE SAME

(71) Applicant: TAIWAN SEMICONDUCTOR MANUFACTURING COMPANY LTD., HSINCHU (TW)

(72) Inventor: HUNG-TE LIN, HSINCHU COUNTY (TW)

(21) Appl. No.: 19/181,381

(22) Filed: Apr. 17, 2025

(51) Int. Cl. H10D 84/00; H01L 23/522; H01L 23/528; H10D 1/00; H10D 1/68; H10D 8/00; H10D 8/01; H10D 62/10; H10D 62/60; H10D 84/01

(52) U.S. Cl. CPC H10D 84/204; H10D 1/043; H10D 1/716; H10D 8/045; H10D 8/422; H10D 62/124; H10D 62/60; H10D 84/01; H10W 20/42; H10W 20/435

(57) ABSTRACT

The present disclosure provides a semiconductor device. The semiconductor device includes: a substrate; a doped layer of a first conductivity type in the substrate; a plurality of isolation members, disposed over the doped layer; a plurality of doped regions of a second conductivity type, disposed over the doped layer, wherein the plurality of doped regions and the plurality of isolation members are alternately arranged with each other; and a capacitor structure disposed over the plurality of isolation members, wherein a bottom of the capacitor structure is in direct contact and coupled to each of the plurality of doped regions.

### BACKGROUND

A capacitor is a device including a dielectric layer sandwiched by a pair of electrodes. A capacitor may be employed as a charge storage unit in a dynamic random-access memory (DRAM), provided as a stand-alone semiconductor chip, or embedded in a system-on-chip (SoC) semiconductor chip. In addition, a capacitor may also be employed in a variety of circuit applications such as a charge pump or a capacitive analog component in a radio-frequency (RF) circuit.

### BRIEF DESCRIPTION OF THE DRAWINGS

Aspects of the embodiments of the present disclosure are best understood from the following detailed description when read with the accompanying figures. It should be noted that, in accordance with the standard practice in the industry, various structures are not drawn to scale. In fact, the dimensions of the various structures can be arbitrarily increased or reduced for clarity of discussion.

FIG. 1 is a flow diagram showing a method of fabricating a semiconductor device, in accordance with some embodiments of the present disclosure.

FIGS. 2 to 7, 8A to 8H, 9, 10A to 10E, 11A to 11E, 12A to 12C, 13, 14A to 14J, 15, 16, 17A to 17C, 18A, 18C, 20 and 21A are schematic cross-sectional views illustrating sequential operations of the method shown in FIG. 1, in accordance with some embodiments of the present disclosure.

FIGS. 18B, 18D, 19A, 19B and 21B are schematic top views illustrating some operations of the method shown in FIG. 1, in accordance with some embodiments of the present disclosure.

FIG. 22 is a simplified circuit diagram of the semiconductor device formed using the method in FIG. 1, in accordance with some embodiments of the present disclosure.

FIGS. 23 to 26 respectively show other semiconductor devices similar to the semiconductor device formed using the method in FIG. 1, in accordance with various embodiments of the present disclosure.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features can be formed between the first and second features, such that the first and second features are not in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “upper,” “on” and the like, can be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus can be otherwise oriented (rotated 90 degrees or at other orientations) and the spatially relative descriptors used herein may likewise be interpreted accordingly.

As used herein, although terms such as “first,” “second” and “third” describe various elements, components, regions, layers and/or sections, these elements, components, regions, layers and/or sections should not be limited by these terms. These terms may only be used to distinguish one element, component, region, layer or section from another. Terms such as “first,” “second” and “third” when used herein do not imply a sequence or order unless clearly indicated by the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the normal deviation found in the respective testing measurements. Also, as used herein, the terms “substantially,” “approximately” and “about” generally mean within a value or range that can be contemplated by people having ordinary skill in the art. Alternatively, the terms “substantially,” “approximately” and “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages such as those for quantities of materials, durations of time, temperatures, operating conditions, ratios of amounts, and the likes thereof disclosed herein should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as from one endpoint to another endpoint or between two endpoints. All ranges disclosed herein are inclusive of the endpoints, unless specified otherwise.

A trench capacitor is a small three-dimensional device formed by etching a trench into a semiconductor substrate. A deep trench capacitor is used to provide capacitance to various integrated circuits (ICs). Deep trench capacitors can be used in a variety of semiconductor chips for high areal capacitance and low device leakage. Typically, a deep trench capacitor provides a capacitance in a range from 4 femtofarad (fF) to 120 fF. An advantage of using the deep trench capacitor over package structures is that the deep trench capacitor can be placed close to the desired processing units. Additionally, the deep trench capacitor can provide greater capacitance per unit area. Deep trench capacitors are commonly embedded in integrated passive devices and used in place of ceramic capacitors to reduce sizes and costs and increase functionality of semiconductor devices.

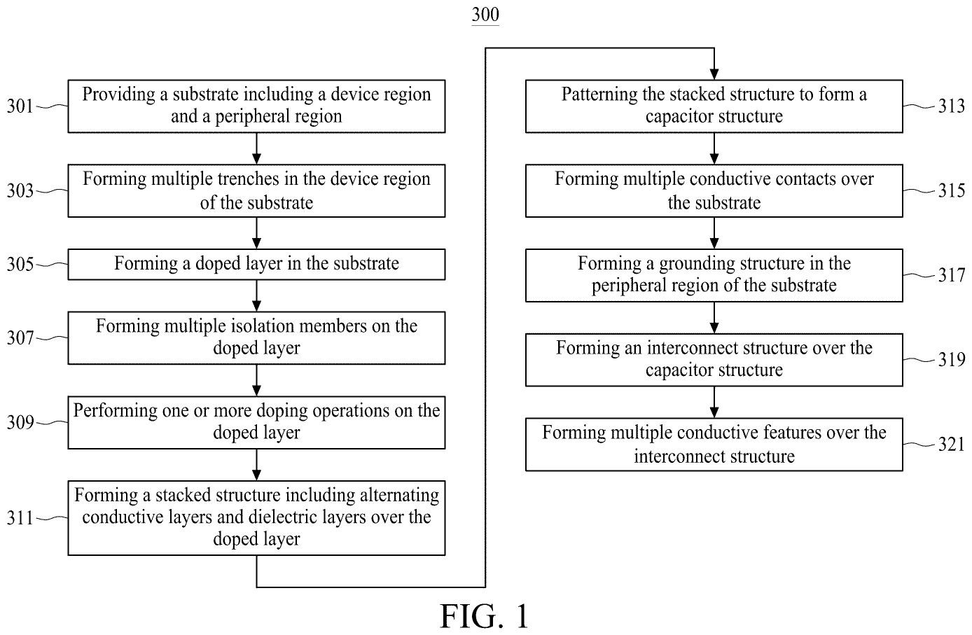

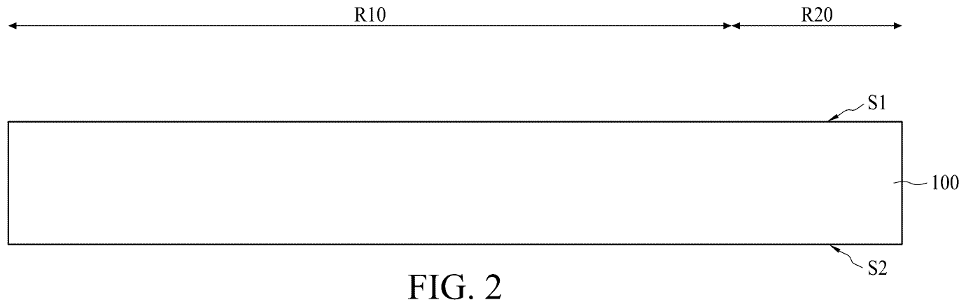

FIG. 1 is a flow diagram showing a method 300 of fabricating a semiconductor device 10. In some embodiments, the semiconductor device 10 includes one or more deep trench capacitors. FIGS. 2 to 21C are schematic cross-sectional views and top views illustrating sequential operations of the method 300 shown in FIG. 1. Additional operations can be provided before, during, and after each operation of the method 300. Some operations of the method 300 can be replaced, eliminated, repeated or relocated for other embodiments. The method 300 is an example, and is not intended to limit the present disclosure beyond what is explicitly recited in the claims.

In operation 301 of FIG. 1, a substrate 100 including a device region R10 and a peripheral region R20 is provided, as shown in FIG. 2. In some embodiments, the device region R10 is a region where one or more active devices, such as transistors, and/or passive devices, such as resistors, capacitors or inductors, are formed. In some embodiments, the peripheral region R20 surrounds the device region R10. The substrate 100 has a first surface S1 and a second surface S2 opposite to the first surface S1. In some embodiments, the active and passive devices are disposed over the first surface S1. The substrate 100 may be a silicon wafer. In some embodiments, the substrate 100 is a silicon-on-insulator (SOI) substrate, a polysilicon substrate, or an amorphous silicon substrate. The substrate 100 may include a suitable elementary semiconductor, such as germanium (Ge) or diamond. In some embodiments, the substrate 100 includes a compound semiconductor, such as silicon germanium (SiGe), silicon carbide (SiC), gallium arsenide (GaAs), gallium nitride (GaN), indium phosphide (InP) or the like.

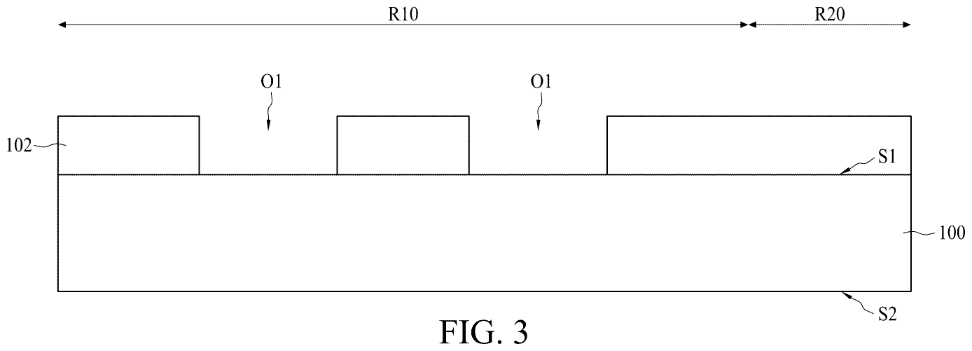

In operation 303 of FIG. 1, multiple trenches T10 are formed in the device region R10 of the substrate 100, as shown in FIGS. 3 to 5. The trenches T10 may be formed using one or more lithographic and etching operations. For example, a double-patterning or multi-patterning technique can be used to form the trenches T10.

Referring to FIG. 3, an etching mask 102 is formed on the first surface S1 of the substrate 100. The etching mask 102 may be a patterned photoresist or a patterned hard mask. In some embodiments, the patterned hard mask may be a single layer including, for example but not limited thereto, a silicon nitride layer. In other embodiments, the patterned hard mask may be a multiple layer. In some embodiments, the etching mask 102 may include multiple openings O1 that expose portions of the first surface S1.

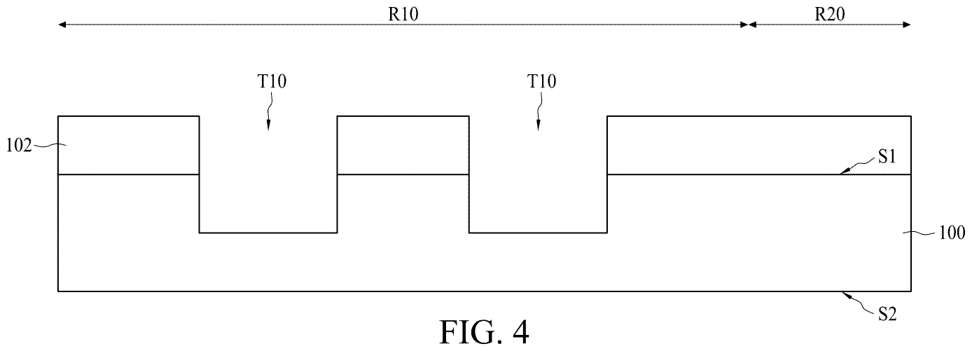

Referring to FIG. 4, suitable etching operation such as, for example but not limited thereto, a dry etching operation or a reactive ion etch (RIE) operation is performed on the substrate 100. Portions of the substrate 100 are etched through the openings O1 of the etching mask 102 until multiple trenches T10 extending into the substrate 100 are formed.

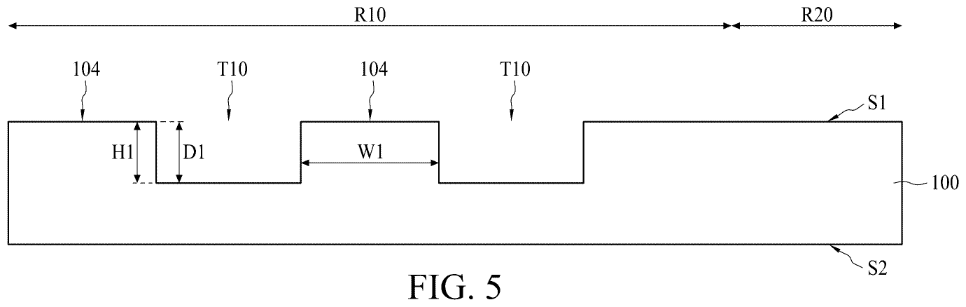

Referring to FIG. 5, the etching mask 102 is removed, and multiple protrusions 104 are exposed. The protrusions 104 are alternately arranged with the trenches T10. The protrusion 104 has a width W1. The trenches T10 extend downward from the first surface S1 of the substrate 100. A depth D1 of the trench T10 is substantially equal to a height H1 of the protrusion 104. In some embodiments, the depth D1 is between about 20 micrometers (μm) and about 100 μm. The trench T10 may have a high aspect ratio (i.e., a ratio of a trench's depth to its width). Therefore, in some cases, the trench T10 may be referred to as a deep trench. The trenches T10 are configured for formation of a deep trench capacitor. The high aspect ratio of the trenches T10 is used to increase a capacitance density of the deep trench capacitor.

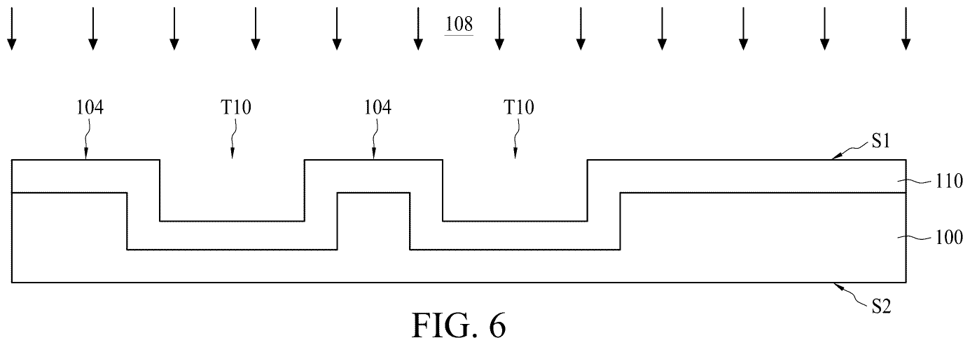

In operation 305 of FIG. 1, a doped layer 110 is formed in the substrate 100, as shown in FIG. 6. In some embodiments, a doping operation is performed on the first surface S1 and an upper portion of the substrate 100 to form the doped layer 110. Dopants of a first conductivity type may be doped to form the doped layer 110. In some embodiments, the first conductivity type is P type. In such embodiments, p-type dopants 108 such as boron (B), gallium (Ga) or indium (In) ions may be doped into the etched substrate 100. In some embodiments, a dose of the P-type dopants 108 is between about 1×10¹² atoms/cm² and about 8×10¹³ atoms/cm². The P-type dopants 108 enter from the first surface S1 of the substrate 100 and into the substrate 100. In some embodiments, a thermal operation such as rapid thermal processing (RTP) is performed on the substrate 100 after the doping operation. Due to the heating, the P-type dopants 108 may diffuse to a predetermined depth of the substrate 100 to form the doped layer 110. The doped layer 110 may be referred to as a P well in the substrate 100. Each protrusion 104 may be conductive because it contains P-type dopants 108. In some embodiments, the order of operations 303 and 305 is interchangeable. That is, the doped layer 110 can be formed in the substrate 100, followed by the etching of the substrate 100 with the doped layer 110 to form the trenches T10.

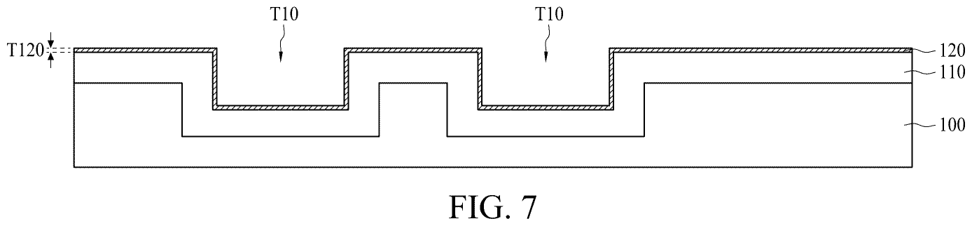

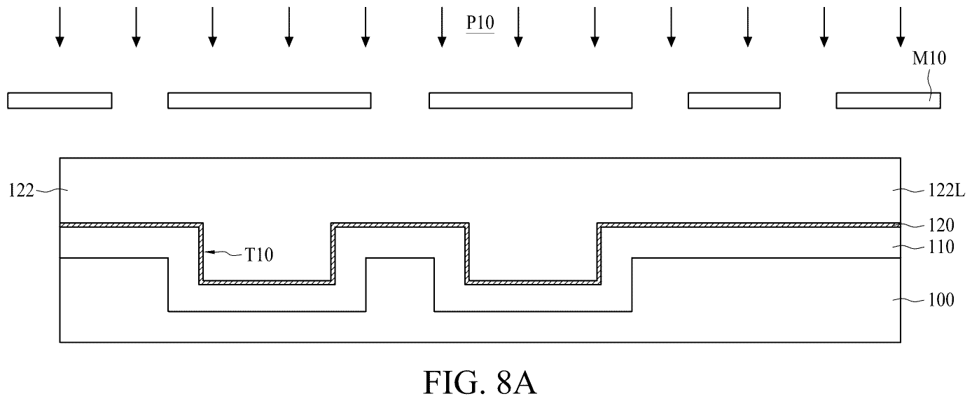

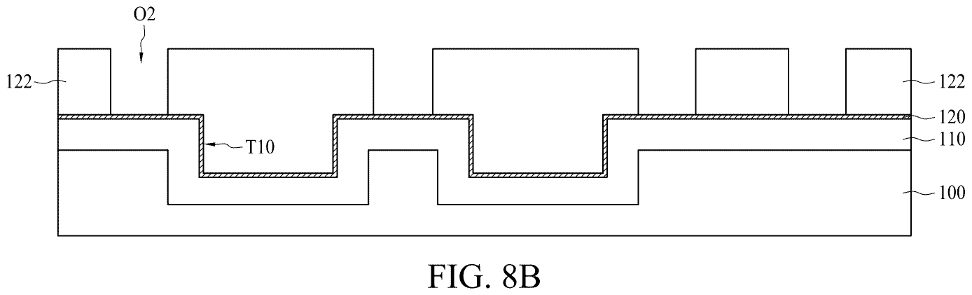

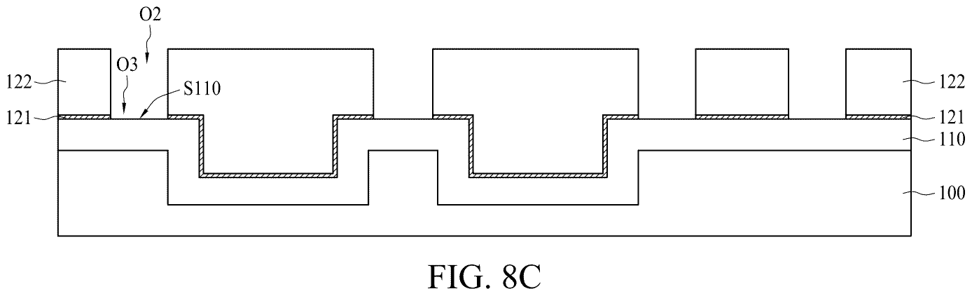

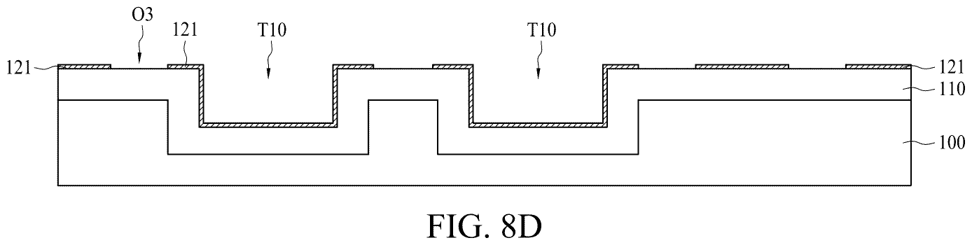

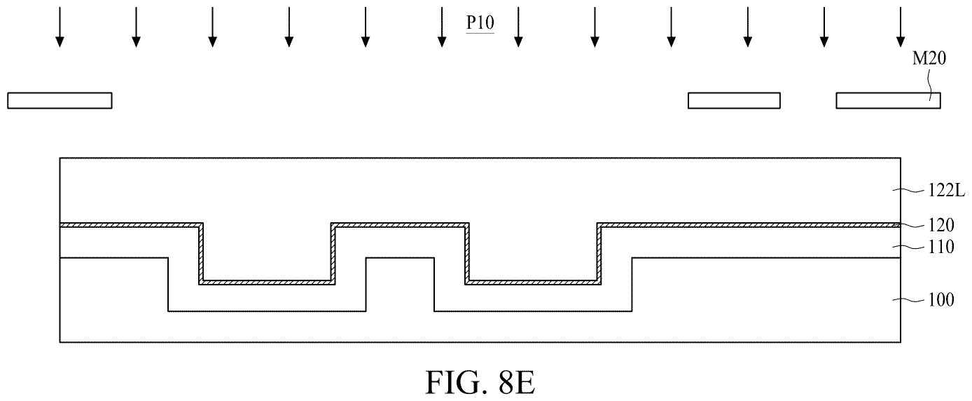

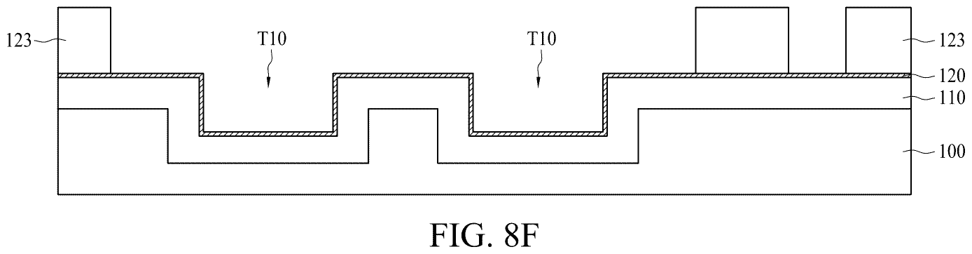

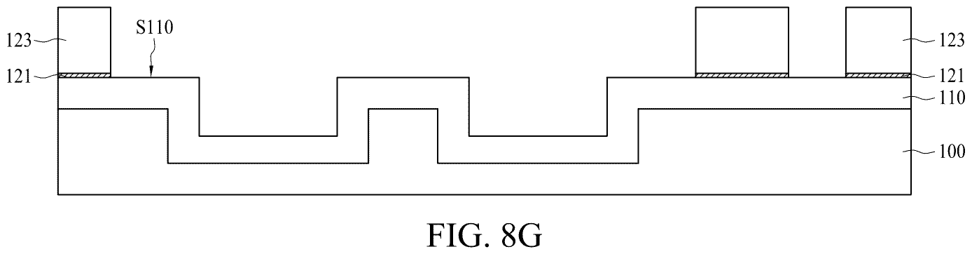

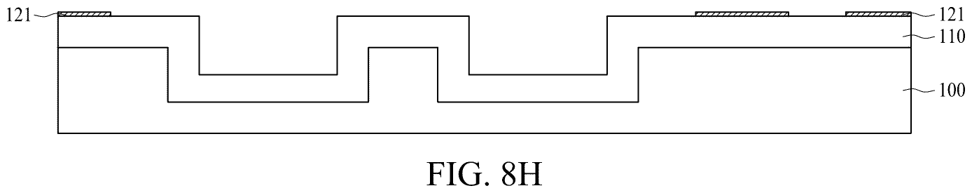

In operation 307 of FIG. 1, multiple isolation members 121 are formed on the doped layer 110, as shown in FIGS. 7 and 8A to 8H. Referring to FIG. 7, an isolation layer 120 including silicon oxide (SiO₂) is formed on the doped layer 110. In some embodiments, the isolation layer 120 is formed by thermal oxidation. The substrate 100 may be placed in a furnace and reacted with oxygen (O₂) at a high temperature. Silicon at a top portion of the doped layer 110 is oxidized to form silicon oxide, thus forming the isolation layer 120. That is, the isolation layer 120 is formed by converting a portion of the doped layer 110, which is a portion of the substrate 100, into silicon oxide. In other embodiments, the isolation layer 120 is formed by chemical vapor deposition (CVD). Silicon oxide can be directly deposited on the doped layer 110, thus forming the isolation layer 120. In some embodiments, the isolation layer 120 is conformally formed on surfaces of the doped layer 110. In some embodiments, a thickness T120 of the isolation layer 120 is between about 100 angstroms (Å) and about 200 Å.

Referring to FIG. 8A, in some embodiments, a photoresist layer 122L is coated on the isolation layer 120. The photoresist layer 122L is exposed to a radiation P10 via a photomask M10. In other embodiments, a hard mask layer is used instead of the photoresist layer 122L.

Referring to FIG. 8B, after exposure, portions of the photoresist layer 122L are developed, and an etching mask 122 is formed on the isolation layer 120. In embodiments where a hard mask layer is used, the hard mask layer is patterned to form the etching mask 122.

The etching mask 122 includes multiple openings O2 that expose portions of the underlying isolation layer 120. In other embodiments, the etching mask 122 is a nitride hard mask. In some embodiments, as shown in FIG. 8B, the openings O2 of the etching mask 122 are offset from the trenches T10, but the present disclosure is not limited thereto.

Referring to FIG. 8C, a suitable etching operation such as, for example but not limited thereto, a dry etching operation or an RIE operation is performed on the isolation layer 120. In some embodiments, the isolation layer 120 is etched through the openings O2 of the etching mask 122 until portions of a top surface S110 of the doped layer 110 are exposed. In such embodiments, the isolation layer 120 is cut into multiple isolation members 121 separated by openings O3.

Referring to FIG. 8D, the etching mask 122 is removed. The isolation members 121 may have substantially same or different lengths.

Referring to FIG. 8E, the isolation members 121 having a different profile may be formed. The photoresist layer 122L may be exposed to the radiation P10 via a photomask M20 having a pattern different from that of the photomask M10.

Referring to FIG. 8F, after exposure, portions of the photoresist layer 122L are developed, and an etching mask 123 is formed on the isolation layer 120. The etching mask 123 has a pattern different from that of the etching mask 122. In embodiments where a hard mask layer instead of the photoresist layer 122L is used, the hard mask layer is patterned to form the etching mask 123.

In some embodiments, as shown in FIG. 8F, the trenches T10 are exposed through the etching mask 123, but the present disclosure is not limited thereto.

Referring to FIG. 8G, a suitable etching operation such as, for example but not limited thereto, a dry etching operation or an RIE operation is performed on the isolation layer 120. The isolation layer 120 is etched through the etching mask 123 until portions of the top surface S110 of the doped layer 110 are exposed.

Referring to FIG. 8H, the etching mask 123 is removed. The isolation members 121 shown in FIGS. 8D and 8H have different profiles according to various embodiments of the present disclosure.

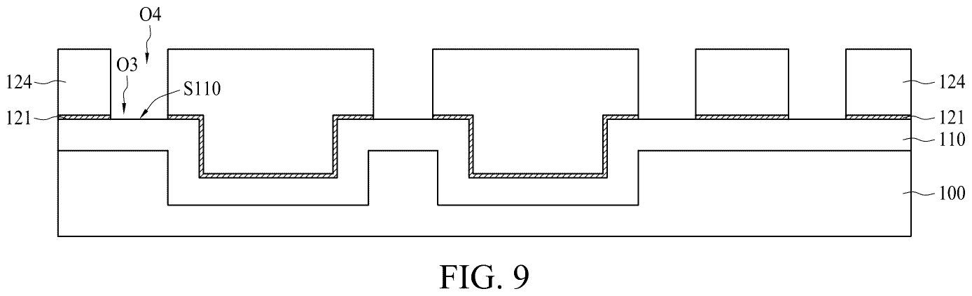

In operation 309 of FIG. 1, one or more doping operations are performed on the doped layer 110, as shown in FIGS. 9, 10A to 10E and 11A to 11E.

Referring to FIG. 9, an implant mask 124 is formed on the isolation members 121. The implant mask 124 may be a patterned photoresist. The implant mask 124 includes openings O4 that allow for passage of dopants. In some embodiments, the openings O3 and O4 collectively expose portions of the top surface S110 of the doped layer 110. In some embodiments, a width of the opening O4 is equal to a width of the opening O3. In other embodiments, the width of the opening O4 is greater than the width of the opening O3. In some embodiments, the openings O4 have a same width. In other embodiments, the openings O4 have different widths, although not shown.

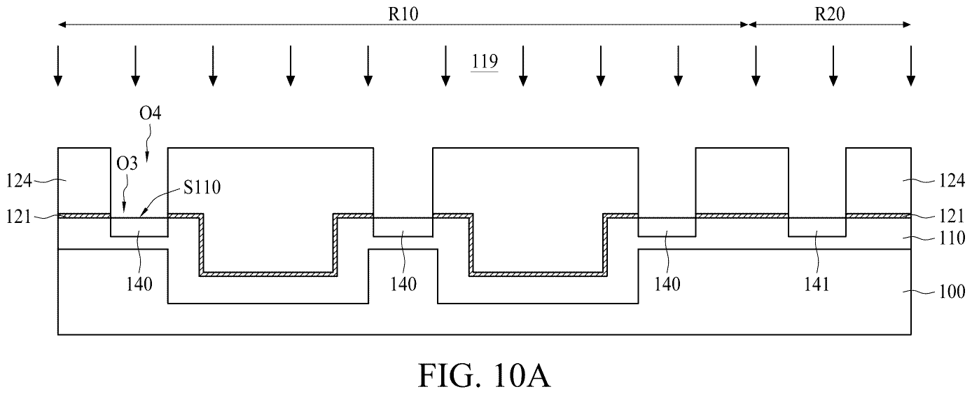

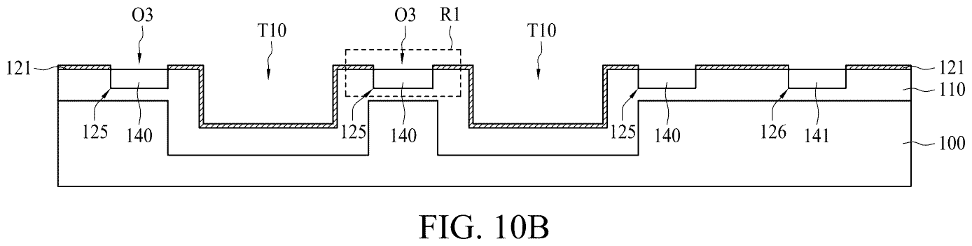

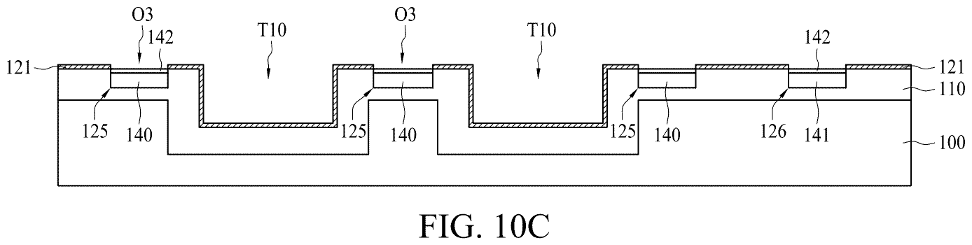

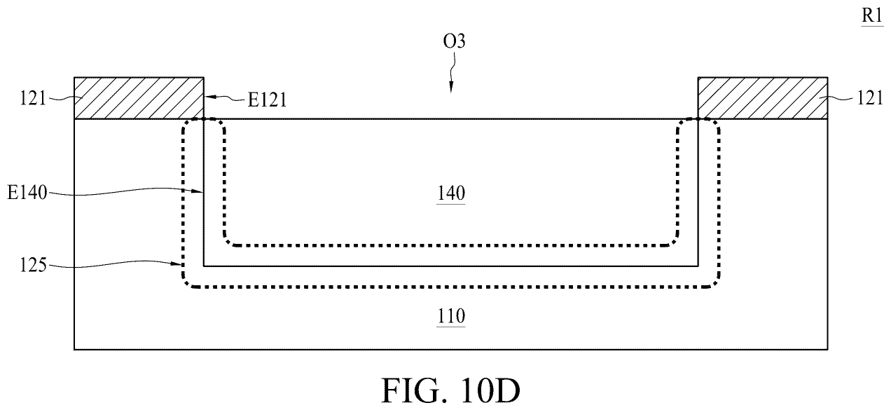

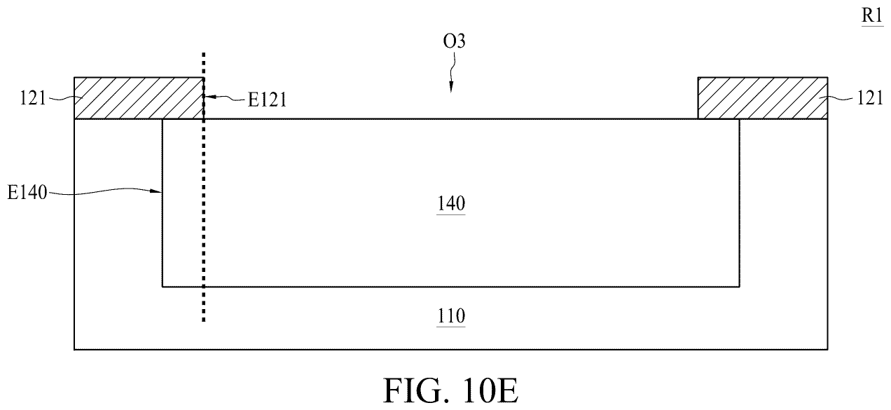

FIGS. 10A to 10E show embodiments where one doping operation is performed. Referring to FIG. 10A, an implantation operation is performed on the doped layer 110. In some embodiments, dopants of a second conductivity type is used. The second conductivity type is complementary to the first conductivity type. In such embodiments, n-type dopants 119 such as phosphorus (P) or arsenic (As) ions may be doped into exposed portions of the doped layer 110. In some embodiments, a dose of the N-type dopants 119 is between about 2×10¹⁴ atoms/cm² and about 1×10¹⁶ atoms/cm². In some embodiments, the implant mask 124 and the isolation members 121 block the N-type dopants 119 from entering masked regions of the doped layer 110. In other embodiments, when the implant mask 124 is absent, the isolation members 121 are used to block the N-type dopants 119 from entering the masked regions of the doped layer 110. The N-type dopants 119 pass through the openings O3 and O4 into the doped layer 110. The N-type dopants 119 enter from the top surface S110 of the doped layer 110 and diffuse in the doped layer 110 to form multiple doped regions 140 and a doped region 141. For ease of discussion, the doped region 140 is a doped region formed in the device region R10, and the doped region 141 is a doped region formed in the peripheral region R20. The doped regions 140 and 141 are formed at upper portions of the doped layer 110. As shown in FIG. 10A, a thickness of each of the doped regions 140 and 141 is less than a thickness of the doped layer 110. In some embodiments, the doped regions 140 and 141 have a same thickness. In other embodiments, the doped regions 140 and 141 have different thicknesses.

Referring to FIG. 10B, the implant masks 124 are removed using, for example, a stripping or wet cleaning operation. In some embodiments, the doped regions 140 and 141 and the isolation members 121 are alternately arranged with each other. In some embodiments, multiple diodes 125 are formed of P-N junctions between the P-type doped layer 110 and the N-type doped regions 140, and a diode 126 is formed of a P-N junction between the P-type doped layer 110 and the N-type doped region 141. The diodes 125 are formed in the device region R10 and the diode 126 is formed in the peripheral region R20.

Referring to FIG. 10C, in some embodiments, a silicidation process is performed on the doped regions 140 and 141. Accordingly, metal silicide layers 142 are respectively formed on the doped regions 140 and 141. The metal silicide layer 142 includes CoSi, TiSi, NiSi, or the like. The metal silicide layers 142 can be used to improve electrical conductivity when the doped regions 140 and 141 are electrically connected to components subsequently formed over the doped regions 140 and 141.

FIGS. 10D and 10E are enlarged views of a portion R1 in FIG. 10B according to various embodiments of the present disclosure. Referring to FIG. 10D, in some embodiments, an edge E140 of the doped region 140 is substantially aligned with an edge E121 of the isolation member 121. In some embodiments, the N-type doped region 140 contains freely-moving electrons, while the P-type doped layer 110 contains freely-moving electron holes. A depletion region is formed near a boundary of the doped layer 110 and the doped region 140. As the freely-moving electrons fill the available holes, an electric current is allowed to pass through the diode 125 in one direction.

Referring to FIG. 10E, in other embodiments, as the N-type dopants 119 diffuse horizontally and vertically in the doped layer 110, the edge E140 of the doped region 140 is offset from the edge E121 of the isolation member 121. Some of the N-type dopants 119 may diffuse to regions under the isolation members 121. Therefore, in some embodiments, the doped region 140 is partially overlapped by the isolation member 121.

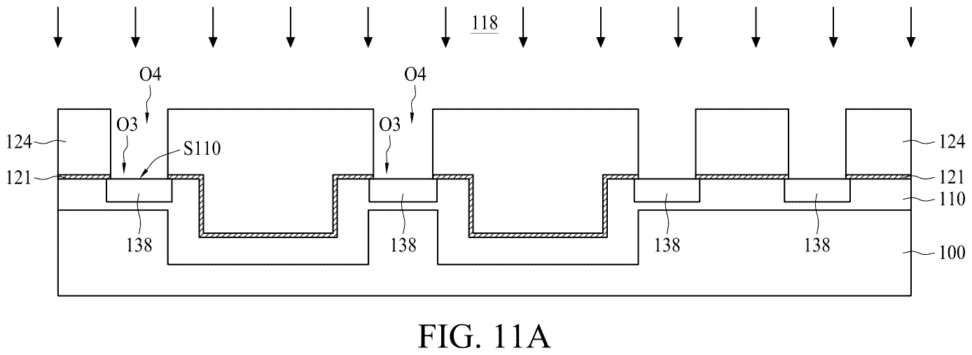

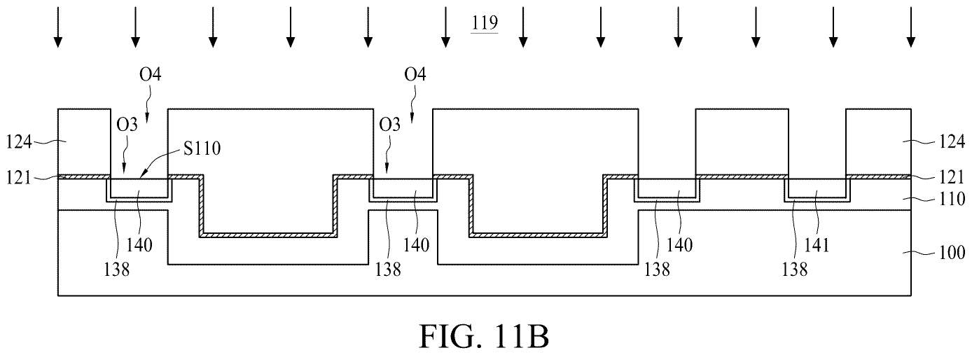

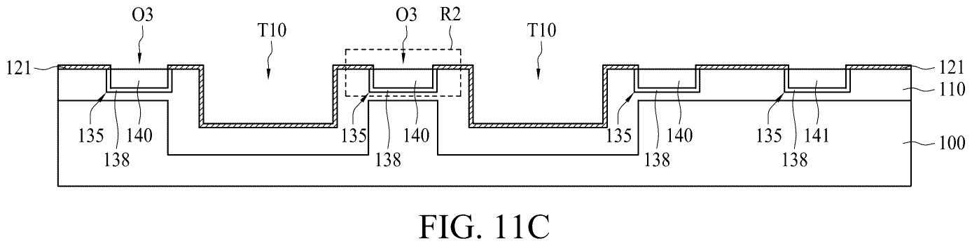

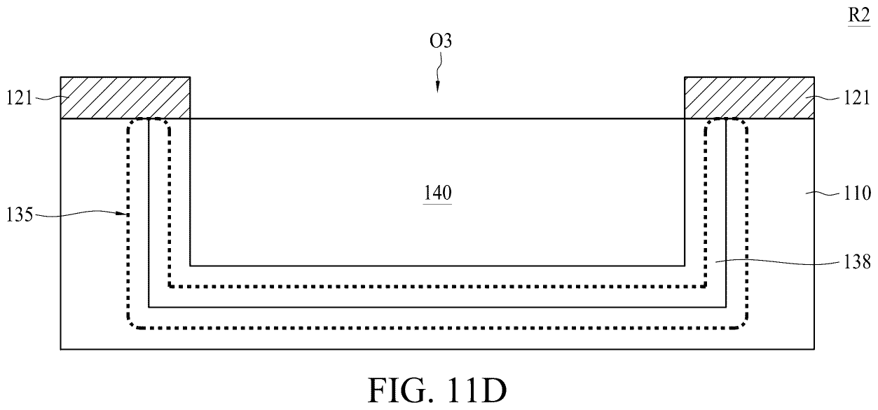

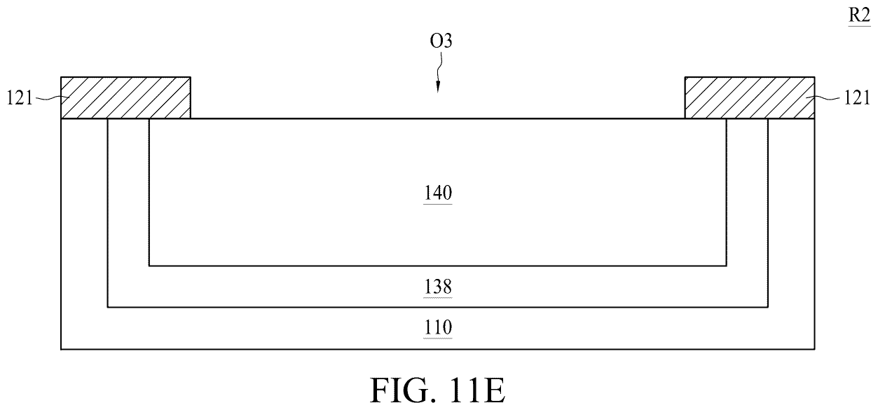

FIGS. 11A to 11E show embodiments where multiple implantation operations are performed.

Referring to FIG. 11A, a first doping operation is performed on the doped layer 110. In some embodiments, dopants 118 of the second conductivity type (i.e., n-type) is used. In such embodiments, n-type dopants 118 such as phosphorus or arsenic ions may be implanted into exposed portions of the doped layer 110. In some embodiments, a dose of the N-type dopants 118 is between about 3×10¹² atoms/cm² and about 8×10¹³ atoms/cm². In some embodiments, the implant mask 124 and the isolation members 121 block the N-type dopants 118 from entering masked regions of the doped layer 110. In other embodiments, when the implant masks 124 are not used, the isolation members 121 are used to block the N-type dopants 118 from entering the masked regions of the doped layer 110. The N-type dopants 118 pass through the openings O3 and O4 into the doped layer 110. The N-type dopants 118 enter from the top surface S110 of the doped layer 110 and diffuse in the doped layer 110 to form multiple lightly-doped regions 138. The N-type dopants 118 may diffuse horizontally and vertically in the doped layer 110. Some of the N-type dopants 118 may diffuse to regions under the isolation members 121. Therefore, in some embodiments, the lightly-doped region 138 is partially overlapped by the isolation member 121.

Referring to FIG. 11B, a second doping operation is performed on the lightly-doped regions 138. In some embodiments, dopants 118 of the second conductivity type (i.e., n-type) is used. In such embodiments, N-type dopants 119 such as phosphorus or arsenic ions may be implanted into exposed portions of the lightly-doped regions 138. A dose of the N-type dopants 119 is greater than the dose of the N-type dopants 118. In some embodiments, a dose of the N-type dopants 119 is between about 2×10¹⁴ atoms/cm² and about 1×10¹⁶ atoms/cm². In some embodiments, the implant mask 124 and the isolation members 121 block the N-type dopants 119 from entering masked regions of the lightly-doped regions 138. In other embodiments, when the implant mask 124 are not used, the isolation members 121 are used to block the N-type dopants 119 from entering the masked regions of the lightly-doped regions 138. The N-type dopants 119 pass through the openings O3 and O4 into the lightly-doped regions 138. The N-type dopants 119 enter from top surfaces of the lightly-doped regions 138 (which are substantially coplanar with the top surface S110 of the doped layer 110) and diffuse in the lightly-doped regions 138 to form multiple doped regions 140 and 141.

Referring to FIG. 11C, after the lightly-doped regions 138 and the doped regions 140 and 141 are formed, the implant masks 124 are removed using, for example, a stripping or wet cleaning operation. In some embodiments, multiple diodes 135 are formed of P-N junctions between the P-type doped layer 110 and the N-type lightly-doped regions 138.

FIGS. 11D and 11E are enlarged views of a portion R2 in FIG. 11C according to various embodiments of the present disclosure. Referring to FIG. 11D, the doped region 140 is formed within the lightly-doped region 138. In some embodiments, the lightly-doped region 138 surrounds the doped region 140. Because the dose of the N-type dopants 119 is greater than the dose of the N-type dopants 118, the doped region 140 has a concentration of N-type dopants (i.e., an N-type dopant concentration) greater than that of the lightly-doped region 138. The lightly-doped region 138 and the doped region 140 may form a concentration gradient of N-type dopants within the doped layer 110. In some embodiments, the N-type lightly-doped region 138 contains freely-moving electrons, while the P-type doped layer 110 contains freely-moving electron holes. A depletion region is formed near a boundary of the doped layer 110 and the lightly-doped region 138. As the freely-moving electrons fill the available holes, an electric current is allowed to pass through the diode 135 in one direction.

Referring to FIG. 11E, in some embodiments, when both the N-type dopants 118 and the N-type dopants 119 diffuse horizontally and vertically in the doped layer 110, the lightly-doped region 138 and the doped region 140 may be partially overlapped by the isolation member 121.

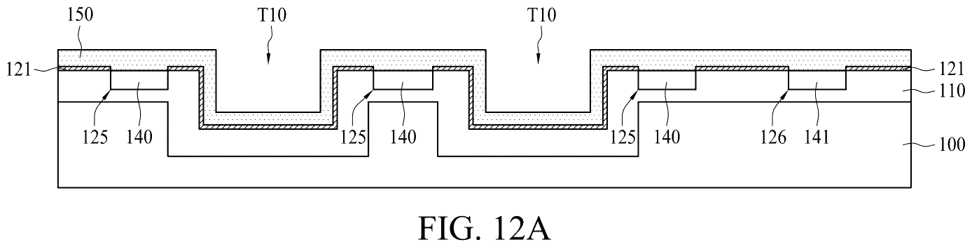

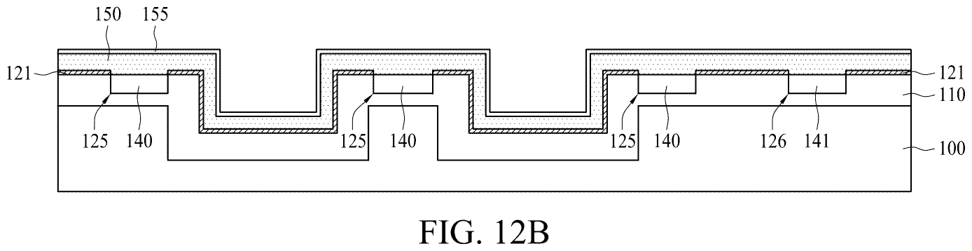

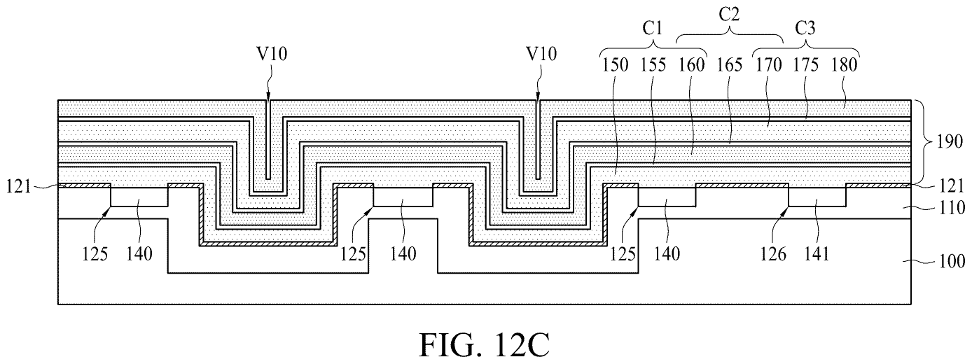

In operation 311 of FIG. 1, a stacked structure 190 including alternating conductive layers and dielectric layers is formed over the doped layer 110, as shown in FIGS. 12A to 12C.

Referring to FIG. 12A, a first conductive layer 150 is deposited on the isolation members 121 and the doped regions 140 and 141. The first conductive layer 150 is conformally formed in the trenches T10 using physical vapor deposition (PVD), atomic layer deposition (ALD), or another suitable method. In some embodiments, the first conductive layer 150 includes polysilicon or metal, such as tungsten (W), copper (Cu), cobalt (Co), aluminum (Al), nickel (Ni), tantalum (Ta), titanium (Ti), molybdenum (Mo), palladium (Pd), platinum (Pt), ruthenium (Ru), iridium (Ir) silver (Ag), gold (Au) or a combination thereof. In some embodiments, the first conductive layer 150 includes titanium nitride (TiN), tantalum nitride (TaN), aluminum copper (AlCu) or other titanium or tantalum-based compounds having an appropriate conductive work function. The openings O3 shown in FIG. 10B may be filled by the first conductive layer 150. In some embodiments, the first conductive layer 150 is in direct contact with and electrically coupled to the doped regions 140 and 141.

Referring to FIG. 12B, a first dielectric layer 155 is conformally formed on the first conductive layer 150 using CVD, ALD, or another suitable method. In some embodiments, the first dielectric layer 155 includes one or more dielectric materials with high dielectric constants (high k) greater than that of silicon oxide (k>3.9). The first dielectric layer 155 may be made of SiN, SiON, Al₂O₃, TiO₂, Ta₂O₅, HfO₂, ZrO₂, HfZrO, HfOₓN_{y}, HfSiₓO_{y}, ZrOₓN_{y}, ZrSiₓO_{y}, HfSiₓO_{y}N_{z}, La₂O₃, Pr₂O₃ or other suitable materials. In some embodiments, a thickness of the first dielectric layer 155 is less than 100 Å. The first dielectric layer 155 may have a dielectric constant between 4 and 1000, with some embodiments having a dielectric constant of approximately 20. In some other embodiments, the first dielectric layer 155 includes a dielectric stack such as an oxide-nitride-oxide (ONO) structure.

Referring to FIG. 12C, the operations shown in FIGS. 12A and 12B are repeatedly performed. That is, a second conductive layer 160 is conformally formed on the first dielectric layer 155, a second dielectric layer 165 is conformally formed on the second conductive layer 160, a third conductive layer 170 is conformally formed on the second dielectric layer 165, a third dielectric layer 175 is conformally formed on the third conductive layer 170, and a fourth conductive layer 180 is conformally formed on the third dielectric layer 175. At this stage, the stacked structure 190 is formed. In some embodiments, the stacked structure 190 includes the first conductive layer 150, the first dielectric layer 155, the second conductive layer 160, the second dielectric layer 165, the third conductive layer 170, the third dielectric layer 175 and the fourth conductive layer 180. However, the stacked structure 190 can include more or fewer conductive layers and dielectric layers in other embodiments. In some embodiments, portions of the stacked structure 190 are formed in the trenches T10.

In some embodiments, the first conductive layer 150, the first dielectric layer 155 and the second conductive layer 160 collectively form a first capacitor C1. The first conductive layer 150 and the second conductive layer 160 may be respectively referred to as a bottom electrode and a top electrode of the first capacitor C1. In some embodiments, the second conductive layer 160, the second dielectric layer 165 and the third conductive layer 170 collectively form a second capacitor C2. The second conductive layer 160 and the third conductive layer 170 may be respectively referred to as a bottom electrode and a top electrode of the second capacitor C2. In some embodiments, the third conductive layer 170, the third dielectric layer 175 and the fourth conductive layer 180 collectively form a third capacitor C3. The third conductive layer 170 and the fourth conductive layer 180 may be respectively referred to as a bottom electrode and a top electrode of the third capacitor C3. A number of the capacitors is not limited. The present disclosure shows three capacitors. However, the number of capacitors can be one, two, three or more.

In some embodiments, the second conductive layer 160 simultaneously functions as the top electrode of the first capacitor C1 and the bottom electrode of the second capacitor C2. In some embodiments, the third conductive layer 170 simultaneously functions as the top electrode of the second capacitor C2 and the bottom electrode of the third capacitor C3. The first, second and third dielectric layers 155, 165 and 175, each of which insulates between the adjacent bottom electrode and the adjacent top electrode, may be referred to as a capacitor dielectric.

The second capacitor C2 is conformally formed on and electrically coupled to the first capacitor C1. The third capacitor C3 is conformally formed on and electrically coupled to the second capacitor C2. In some embodiments, the first, second and third capacitors C1, C2 and C3 are deep trench capacitors formed in parallel and vertically over one another. Each of the first, second and third capacitors C1, C2 and C3 may have a capacitance capable of storing a high volume of electrons. In some embodiments, the trenches T10 shown in FIG. 12A become holes V10 that are sufficiently small. In other embodiments, the trenches T10 are sealed by the fourth conductive layer 180.

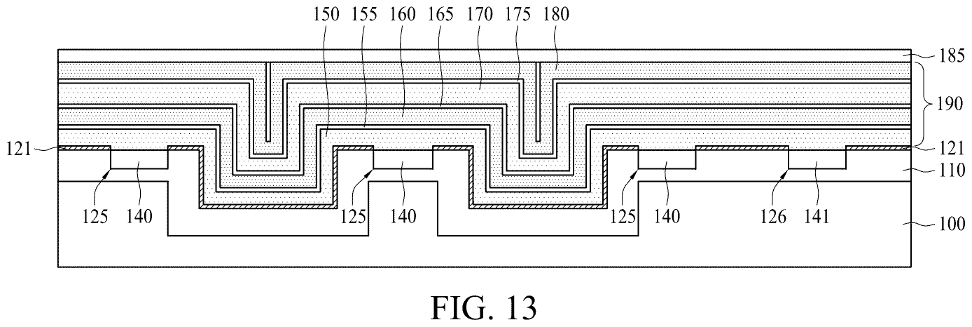

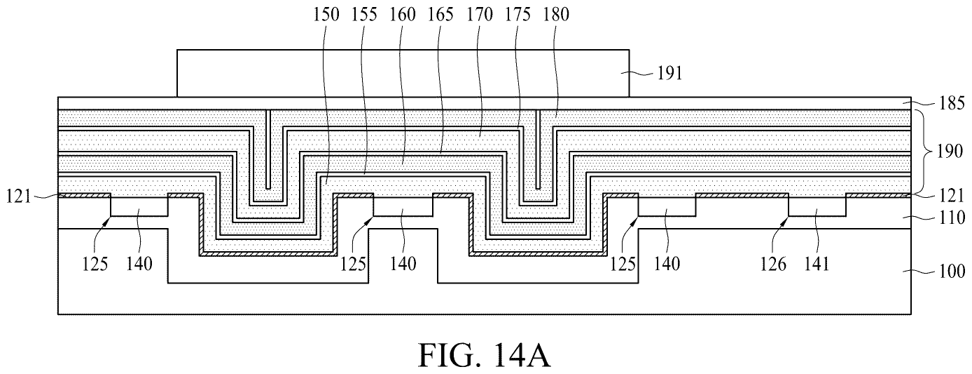

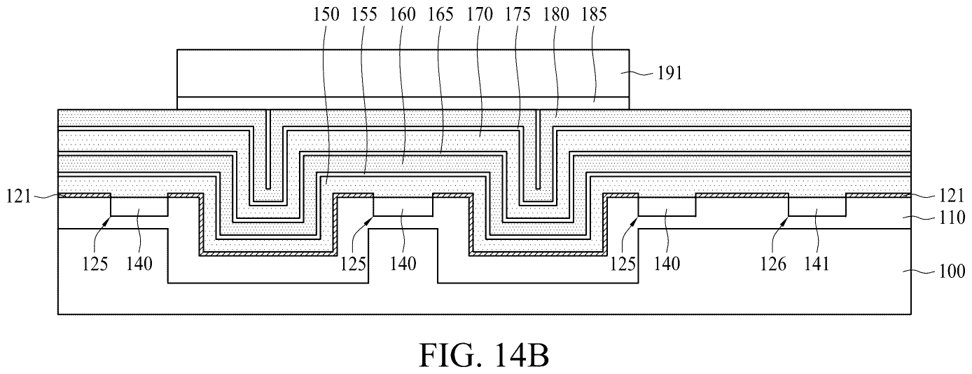

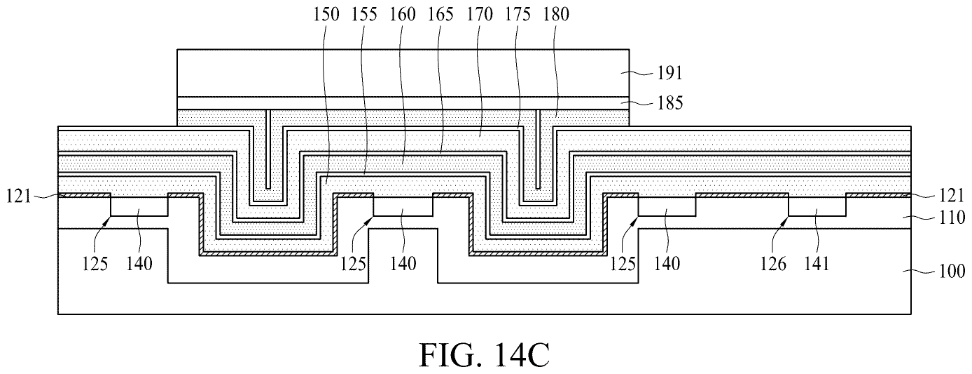

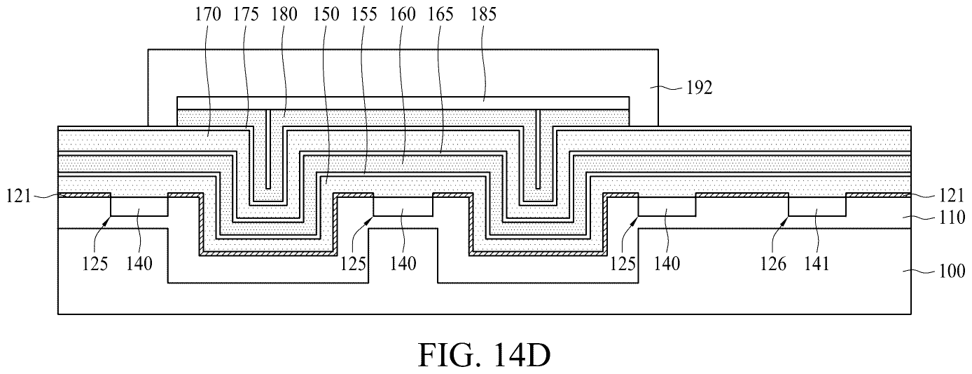

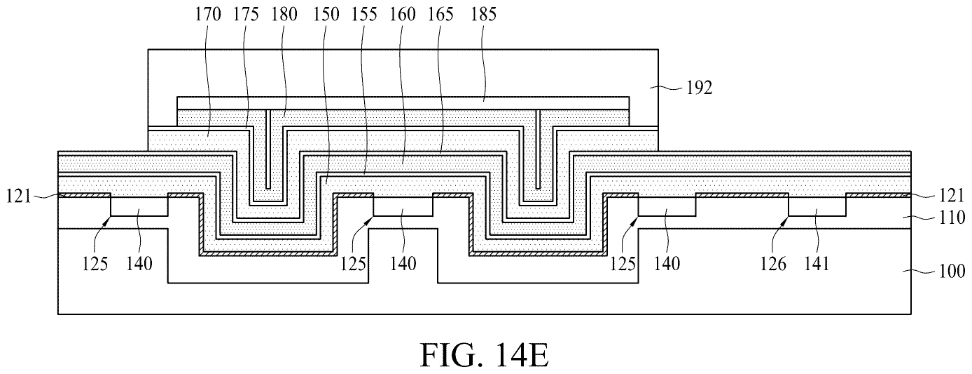

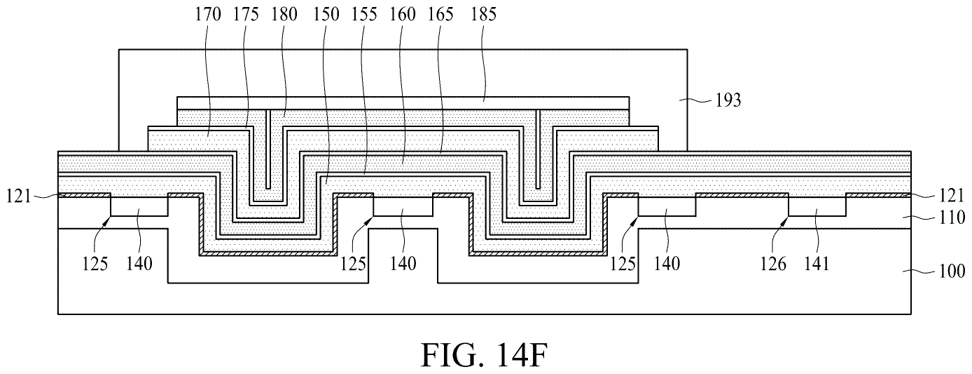

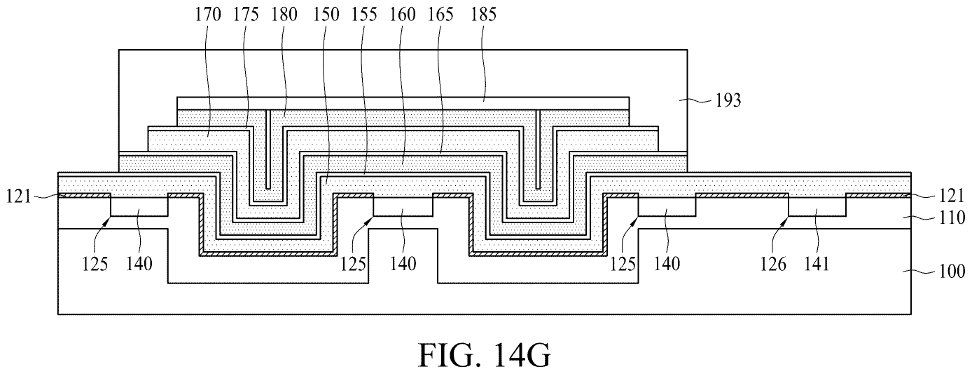

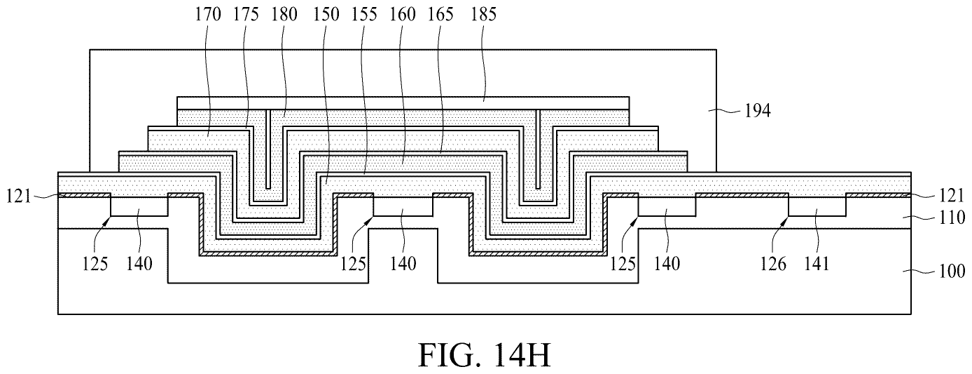

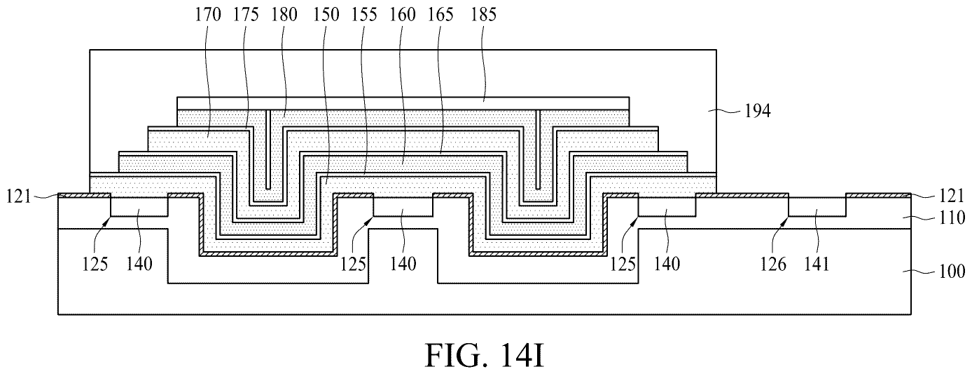

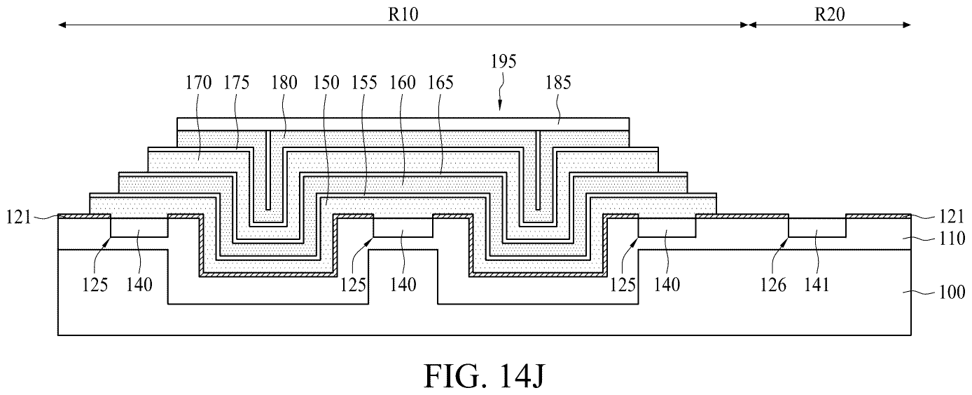

In operation 313 of FIG. 1, the stacked structure 190 is patterned to form a capacitor structure 195, as shown in FIGS. 13 and 14A to 14J. In order to respectively form contacts on the first, second, third and fourth conductive layers 150, 160, 170 and 180, the stacked structure 190 is patterned to have a stepped profile, as shown in FIG. 14J.

Referring to FIG. 13, a capping layer 185 is formed on the stacked structure 190. In order to prevent materials used in subsequent operations such as photoresist or water from entering the holes V10, the holes V10 must be sealed or covered. Therefore, in some embodiments, the capping layer 185 is deposited on the fourth conductive layer 180 using CVD, ALD, or another suitable method. The capping layer 185 completely covers the holes V10 and may partially fill the holes V10. A material of the capping layer 185 may include silicon oxide, silicon nitride, silicon carbide, undoped silicate glass (USG), boro-silicate glass (BSG), tetraethoxysilane (TEOS), a low-k material, or the like.

Referring to FIG. 14A, an etching mask 191 is formed on the capping layer 185. The etching mask 191 may be a patterned photoresist or a nitride hard mask.

Referring to FIG. 14B, portions of the capping layer 185 exposed by the etching mask 191 are removed using an etching operation. The etching operation can be any acceptable etching technique such as RIE, neutral beam etching (NBE), or another suitable method.

Referring to FIG. 14C, portions of the fourth conductive layer 180 exposed by the etching mask 191 and the remaining capping layer 185 are removed using another etching operation.

Referring to FIG. 14D, the etching mask 191 is removed and an etching mask 192 is formed on the remaining stacked structure 190 and the capping layer 185. The etching mask 192 may be a patterned photoresist or a nitride hard mask. The etching masks 191 and 192 are formed using different photomasks and thus have different profiles.

Referring to FIG. 14E, portions of the third dielectric layer 175 and the third conductive layer 170 exposed by the etching mask 192 are removed using one or more etching operations.

Referring to FIG. 14F, the etching mask 192 is removed and an etching mask 193 is formed on the remaining stacking structure 190 and the capping layer 185. The etching mask 193 may be a patterned photoresist or a nitride hard mask. The etching masks 193, 192 and 191 are formed using different photomasks and thus have different profiles.

Referring to FIG. 14G, portions of the second dielectric layer 165 and the second conductive layer 160 exposed by the etching mask 193 are removed using one or more etching operations.

Referring to FIG. 14H, the etching mask 193 is removed and an etching mask 194 is formed on the remaining stacking structure 190 and the capping layer 185. The etching mask 194 may be a patterned photoresist or a nitride hard mask. The etching masks 194, 193, 192 and 191 are formed using different photomasks and thus have different profiles.

Referring to FIG. 14I, portions of the first dielectric layer 155 and the first conductive layer 150 exposed by the etching mask 194 are removed using one or more etching operations.

Referring to FIG. 14J, the etching mask 194 is removed and the formation of the capacitor structure 195 is complete. The capacitor structure 195 has a stepped profile. An area of the first conductive layer 150 is greater than an area of the second conductive layer 160, the area of the second conductive layer 160 is greater than an area of the third conductive layer 170, and the area of the third conductive layer 170 is greater than an area of the fourth conductive layer 180. The first, second and third dielectric layers 155, 165 and 175 are partially exposed for subsequent operations. The capacitor structure 195 covers the doped regions 140 and is separated from the doped region 141. The capacitor structure 195 is electrically coupled to the doped regions 140.

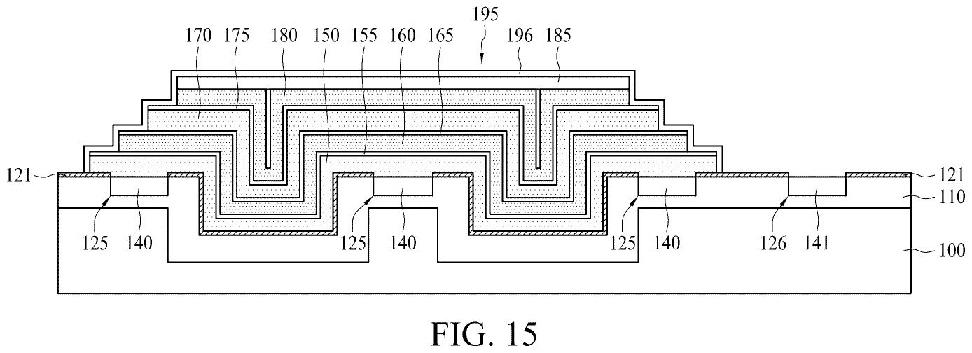

In operation 315 of FIG. 1, multiple conductive contacts are formed over the substrate 100, as shown in FIGS. 15, 16, and 17A to 17C. Referring to FIG. 15, a contact etch stop layer (CESL) 196 is formed on the capacitor structure 195. In some embodiments, the CESL 196 is formed of SiN, SiON, SiCN, SiOCN, the like, or a combination thereof. The CESL 196 can be conformally deposited on the isolation elements 121, the capacitor structure 195 and the doped region 141 using plasma-enhanced CVD (PECVD), low-pressure CVD (LPCVD), ALD, or another suitable method. In some embodiments, the CESL 196 covers the capacitor structure 195, while other elements such as the doped region 141 and some of the isolation members 121 are exposed, but the present disclosure is not limited thereto.

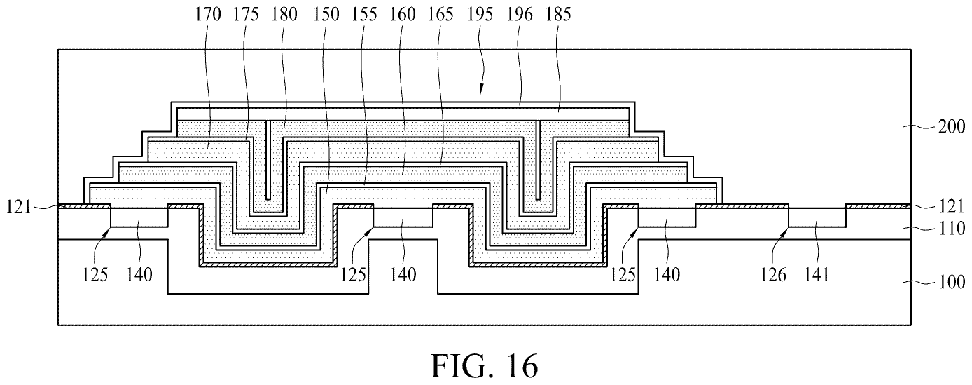

Referring to FIG. 16, a dielectric layer 200 is formed on the substrate 100. A dielectric material including silicon oxide, silicon nitride, PSG, BSG, BPSG, USG, the like, or a combination thereof is deposited on the substrate 100 and surrounds the capacitor structure 195. The dielectric material may be formed using CVD, PECVD, FCVD, spin coating, or another suitable method. After the dielectric material is deposited, a planarization operation such as chemical mechanical polishing (CMP) is used to planarize the dielectric material, thus forming the dielectric layer 200. The dielectric layer 200 surrounds the capacitor structure 195, the capping layer 185 and the CESL 196.

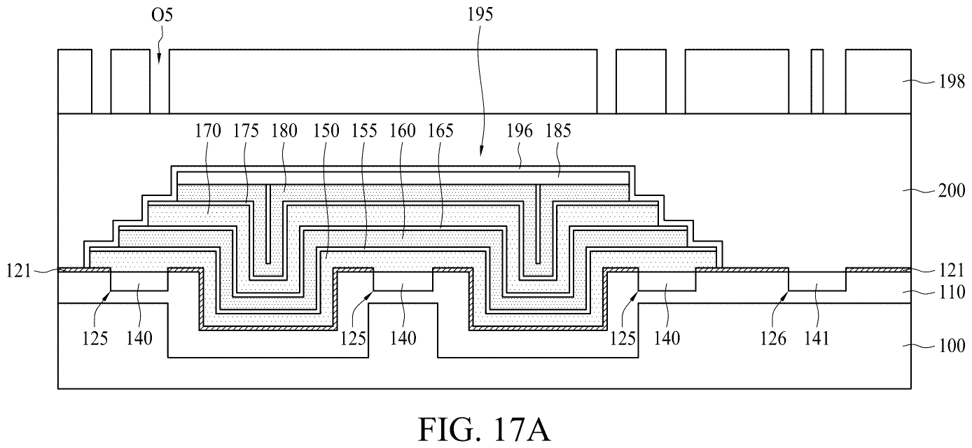

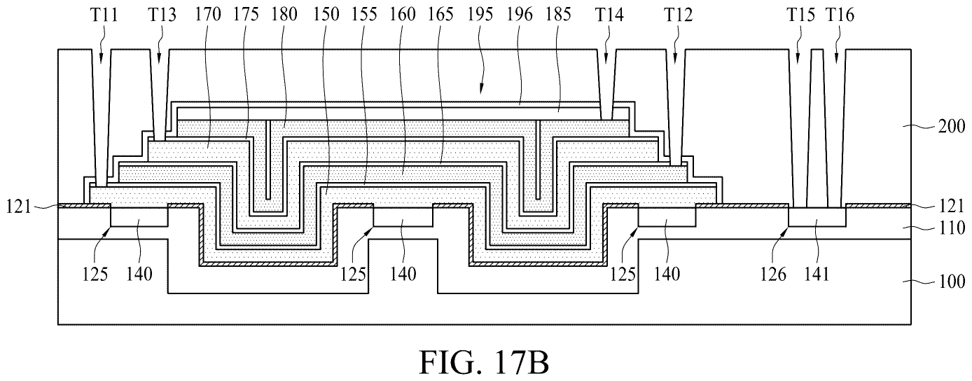

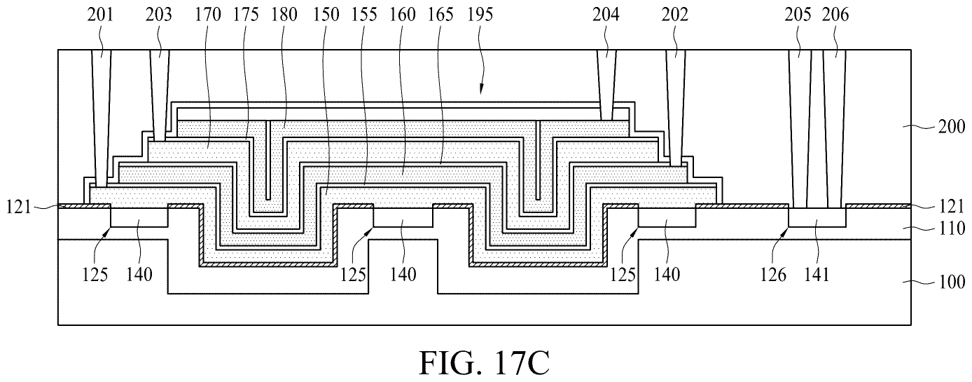

Referring to FIG. 17A, an etching mask 198 is formed on the dielectric layer 200. The etching mask 198 may be a patterned photoresist or a nitride hard mask. The etching mask 198 includes multiple openings O5 that expose portions of the dielectric layer 200.

Referring to FIG. 17B, a suitable etching operation such as, for example but not limited thereto, a dry etching operation or an RIE operation is performed on the dielectric layer 200. Portions of the dielectric layers 155, 165, 175 and 200, the capping layer 185 and the CESL 196 are etched through the openings O5 of the etching mask 198 until multiple trenches T11 to T16 are formed.

Referring to FIG. 17C, a conductive material including W, Cu, Co, Al, Ni, Ta, Ti, Mo, Pd, Pt, Ru, Ir, Ag, Au, the like, or a combination thereof is used to fill the trenches T11 to T16. The conductive material may be formed using PVD, electroplating, electroless plating, or another suitable method. After the trenches T11 to T16 are completely filled by the conductive material, a planarization operation such as CMP is used to remove excess conductive material over a top surface of the dielectric layer 200. As such, conductive contacts 201 to 206 are formed. In some embodiments, the first, second, third and fourth conductive contacts 201, 202, 203 and 204 are respectively formed on and electrically connected to the first, second, third and fourth conductive layers 150, 160, 170 and 180 of the capacitor structure 195. In some embodiments, the fifth and sixth conductive contacts 205 and 206 are formed on and electrically connected to the doped region 141.

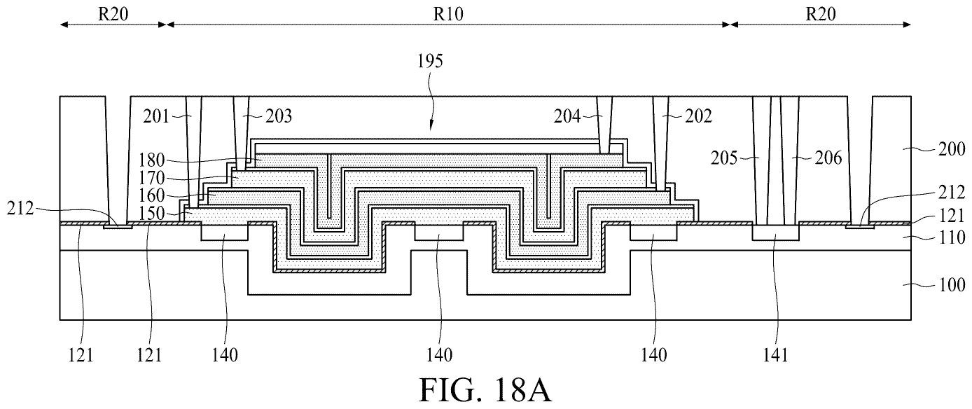

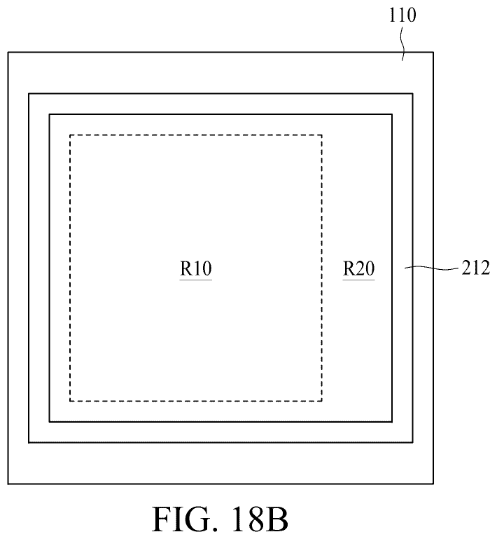

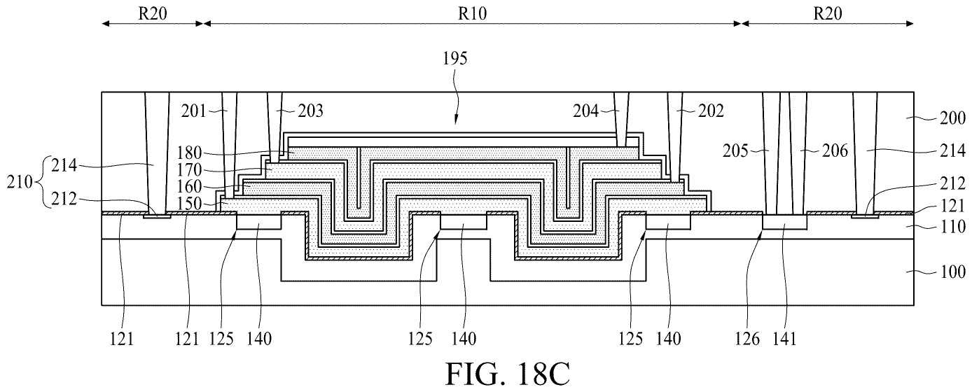

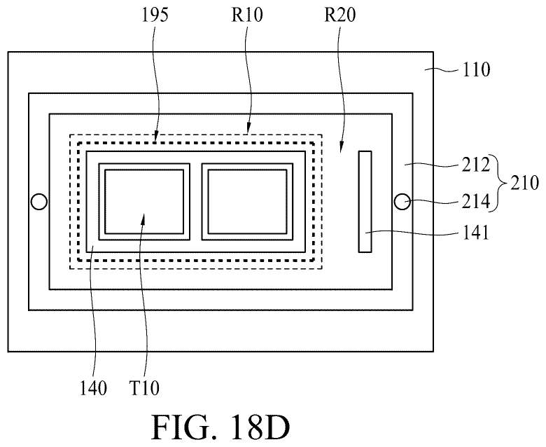

In operation 317 of FIG. 1, a grounding structure 210 is formed in the peripheral region R20 of the substrate 100, as shown in FIGS. 18A to 18D. Referring to FIG. 18A, in some embodiments, a doped region 212 is formed on or within the doped layer 110. The doped region 212 may be formed using a method similar to that of operations 309 and 311. In some embodiments, the dielectric layer 200 and the isolation members 121 in the peripheral region R20 are sequentially etched to expose portions of the underlying doped layer 110. Dopants of the first conductivity type are used. In some embodiments, P-type dopants are implanted into the exposed doped layer 110 to form the doped region 212. In other embodiments, the doped region 212 is formed before or shortly after the doped regions 140 are formed. In some embodiments, a dopant concentration of the doped region 212 is between about 5×10¹⁴ atoms/cm² and about 8×10¹⁵ atoms/cm².

Referring to FIG. 18B, FIG. 18B is a schematic top view of the semiconductor device 10 at the stage shown in FIG. 18A and shows the doped region 212 formed on the doped layer 110. In some embodiments, the doped region 212 has a closed contour. The doped region 212 surrounds the device region R10 in the top view.

Referring to FIG. 18C, one or more contact plugs 214 are formed on and electrically connected to the doped region 212. At this stage, the grounding structure 210 is formed. In some embodiments, the grounding structure 210 includes the doped region 212 and the contact plugs 214.

FIG. 18D is a schematic top view of the semiconductor device 10 at the stage shown in FIG. 18C. Some elements are not shown in FIG. 18D for brevity. In some embodiments, the doped regions 140 are under the capacitor structure 195. In some embodiments, the doped region 212 surrounds the capacitor structure 195 and the doped regions 140 and 141 from the top view. A number of the contact plugs 214 is not limited.

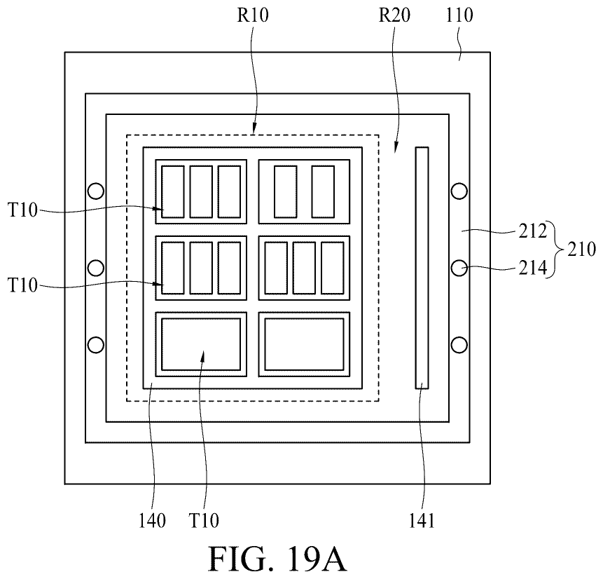

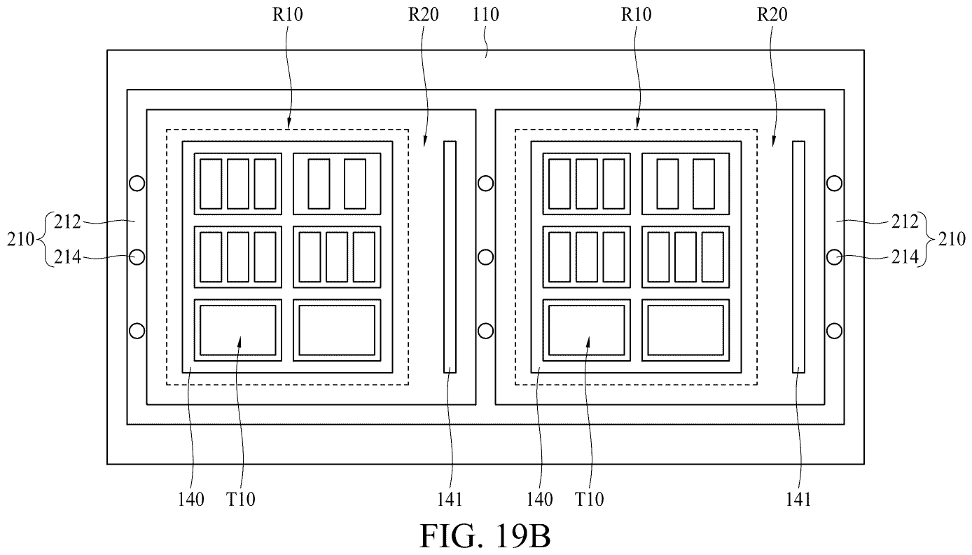

FIGS. 19A and 19B are schematic top views showing different profiles of the doped regions 140 and different profiles of the doped region 212 according to various embodiments of the present disclosure. In some embodiments, all the doped regions 140 are connected to form a single doped region 140 in its entirety, as shown in FIG. 19A. In other embodiments, some of the doped regions 140 are connected to each other, and the doped region 141 is separated from an entirety of the connected doped regions 140. In some embodiments, the doped region 212 surrounds two or more device regions R10, as shown in FIG. 19B. In the top view, the device regions R10 may be separated from each other within the doped region 212, as shown in FIG. 19A, or may be separated by at least a portion of the doped region 212, as shown in FIG. 19B. It should be understood that profiles of the doped regions 140 and 141, profiles of the grounding structure 210 and relative positional relationships between the doped regions 140 (141) and the grounding structure 210 are not limited to those shown in FIGS. 18D and 19A to 19B.

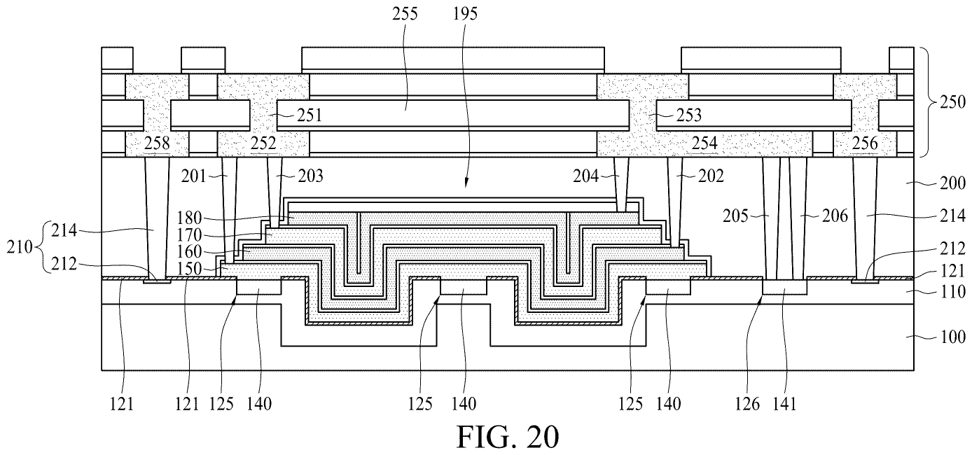

In operation 319 of FIG. 1, an interconnect structure 250 is formed over the capacitor structure 195, as shown in FIG. 20. The formation of the interconnect structure 250 may include a series of lithographic, etching, deposition and planarization operations. The interconnect structure 250 includes multiple vertical conductive vias and multiple horizontal conductive lines surrounded by a dielectric layer 255. Examples of the conductive vias include a first conductive via 251 and a second conductive via 253. Examples of the conductive lines include a first conductive line 252, a second conductive line 254, a third conductive line 256 and a fourth conductive line 258. The conductive vias and the conductive lines are electrically coupled to each other. The vertical conductive vias may connect the horizontal conductive lines in different layers. The dielectric layer 255 may include one or more layers and may be formed using a method same as or similar to the method for forming the dielectric layer 200. The dielectric layer 255 may be denoted as an inter-layer dielectric (ILD) layer or an inter-metal dielectric (IMD) layer.

In some embodiments, the interconnect structure 250 is electrically coupled to the capacitor structure 195, the grounding structure 210 and the doped region 141. The first conductive contact 201 electrically connects the first conductive layer 150 to the first conductive line 252. The second conductive contact 202 electrically connects the second conductive layer 160 to the second conductive line 254. The third conductive contact 203 electrically connects the third conductive layer 170 to the first conductive line 252. The fourth conductive contact 204 electrically connects the fourth conductive layer 180 to the second conductive line 254. The fifth conductive contact 205 and/or the sixth conductive contact 206 electrically connect the doped region 141 to the second conductive line 254. The contact plugs 214 electrically connect the doped region 212 to the third conductive line 256 and/or the fourth conductive line 258. The first conductive contact 201 is electrically connected to the third conductive contact 203 by the first conductive line 252. The second conductive contact 202 is electrically connected to the fourth conductive contact 204 by the second conductive line 254.

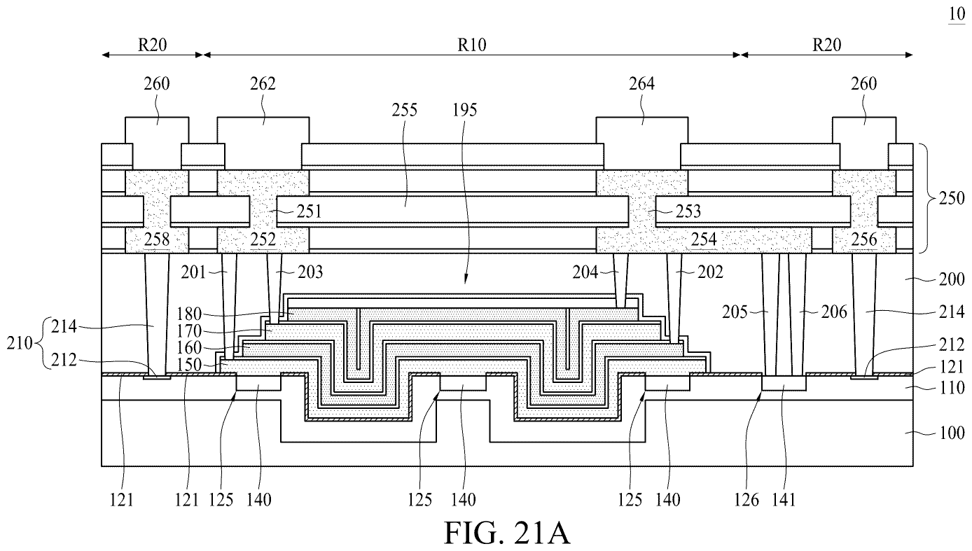

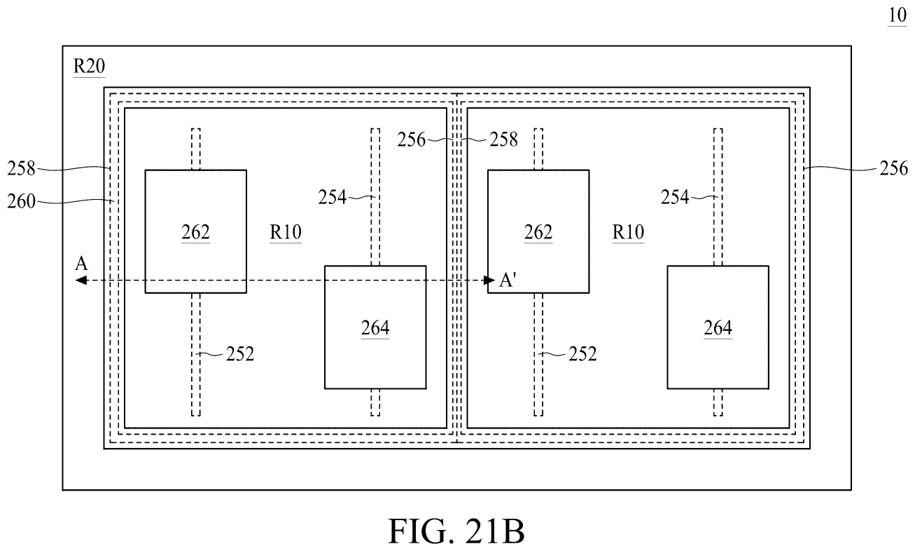

In operation 321 of FIG. 1, multiple conductive features are formed over the interconnect structure 250, as shown in FIGS. 21A to 21C. Referring to FIG. 21A, in some embodiments, a first conductive pad 262 and a second conductive pad 264 are respectively formed over and electrically coupled to the first conductive line 252 and the second conductive line 254. The first and second conductive pads 262 and 264 may be embedded in or at least partially exposed from the interconnect structure 250. A power supply voltage may be applied to the first and second conductive pads 262 and 264. In some embodiments, an antenna structure 260 is formed over and electrically coupled to the third conductive line 256 and the fourth conductive line 258. At this stage, the formation of the semiconductor device 10 is complete.

The semiconductor device 10 includes the doped layer 110 formed in the substrate 100. The doped layer 110 may be formed at an upper portion of the substrate 100. In some embodiments, the doped layer 110 and the substrate 100 are P type. Multiple isolation members 121 are disposed over the doped layer 110. The doped region 141 and the doped regions 140 are disposed over the doped layer 110. The doped regions 140, 141 and the isolation members 121 are alternately arranged with each other. In some embodiments, the doped regions 140 and 141 are N type. The diode 125 is formed by the doped region 140 and the doped layer 110, and the diode 126 is formed by the doped region 141 and the doped layer 110.

The capacitor structure 195 is disposed over the isolation members 121. The capacitor structure 195 includes multiple electrodes and dielectrics alternately stacked and arranged with each other. The first conductive layer 150, which is the bottommost electrode of the capacitor structure 195, is in direct contact with and coupled to the doped regions 140. The first conductive layer 150 is separated from the doped layer 110 by the isolation members 121. The capacitor structure 195 is separated from the doped region 141. The first, second, third and fourth conductive contacts 201, 202, 203 and 204 are respectively disposed on and electrically connected to the first, second, third and fourth conductive layers 150, 160, 170 and 180. The fifth and sixth conductive contacts 205 and 206 are disposed on and electrically connected to the doped region 141. A single conductive contact disposed on the doped region 141 is possible in other embodiments.

The interconnect structure 250 is disposed over and electrically connected to the capacitor structure 195. The first and third conductive contacts 201 and 203 are electrically connected to the first conductive line 252 of the interconnect structure 250. The second, fourth, fifth and sixth conductive contacts 202, 204, 205 and 206 are electrically connected to the second conductive line 254 of the interconnect structure 250. The first conductive line 252 is separated from the second conductive line 254.

The grounding structure 210 including one or more doped regions 212 and one or more contact plugs 214 is disposed on the substrate 100. The doped region 212 is disposed on or within the doped layer 110. In some embodiments, the doped region 212 is P type. The contact plug 214 is disposed adjacent to the capacitor structure 195 and electrically connects the doped region 212 to the interconnect structure 250.

FIG. 21B is a schematic top view of the semiconductor device 10 in FIG. 21A. FIG. 21A may be a cross-sectional view along line A-A′ in FIG. 21B. In some embodiments, a number of the antenna structures 260 is one. In some embodiments, the antenna structure 260 has a closed contour and surrounds one or more device regions R10 in the top view. In other embodiments, multiple separated antenna structures 260 are disposed in the peripheral region R20. In some embodiments, the first conductive pad 262 and the second conductive pad 264 are offset from each other in the top view, as shown in FIG. 21B. In other embodiments, the first conductive pad 262 and the second conductive pad 264 are horizontally aligned with each other in the top view.

In some embodiments, the antenna structure 260 and the grounding structure 210 are used to conduct and collect electrical charges generated during one or more processes or operations for forming the semiconductor device 10. For example, electrical charges accumulating in components of the semiconductor device 10 can flow to the substrate 100 through the antenna structure 260, the interconnect structure 250 and/or the grounding structure 210. Therefore, the capacitor structure 195 can be protected from being damaged by excess electrical charges. In some embodiments, the antenna structure 260 functions as a ground (GND) pad.

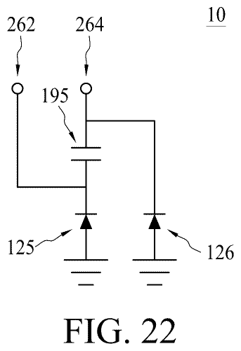

FIG. 22 is a simplified circuit diagram of the semiconductor device 10. One of the three diodes 125 and the diode 126 are shown in FIG. 22. In some embodiments, the diode 125 and the diode 126 have a same reverse turn-on voltage (Vr). A value of the reverse turn-on voltage can be tuned by adjusting dopant concentrations of the doped layer 110 and the doped region 140 and adjusting dopant concentrations of the doped layer 110 and the doped region 141. The value of the reverse turn-on voltage is greater than a value of an operating voltage of the capacitor structure 195 and less than a value of a breakdown voltage of the capacitor structure 195 (i.e., operating voltage<reverse turn-on voltage<breakdown voltage). Therefore, when the capacitor structure 195 is subjected to an instantaneous voltage (i.e., a pulse) greater than the breakdown voltage of the capacitor structure 195, a resulting current will flow to the diodes 125 and 126, and further to the substrate 100. Therefore, the capacitor structure 195 will not be impacted by the pulse. The diodes 125 and 126 may be referred to as protection diodes. Since the diodes 125 and 126 are electrically coupled to the substrate 100, the diodes 125 and 126 can be referred to as GND (i.e., potential=0V). A number of the diodes 125 is not limited. The number of the diodes 125 can be one, two, three or more.

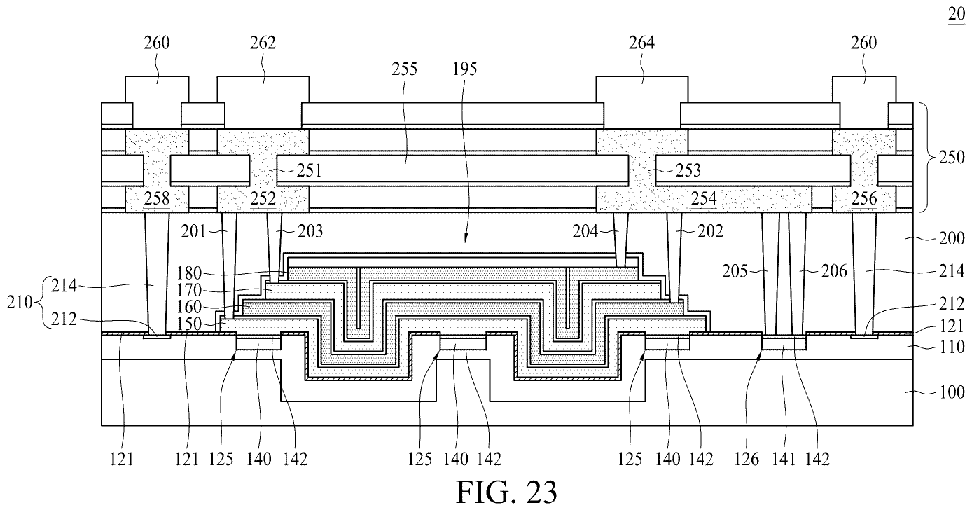

FIGS. 23 to 26 respectively show semiconductor devices 20, 30, 40 and 50 according to various embodiments of the present disclosure. The semiconductor devices 20, 30, 40 and 50 are similar to the semiconductor device 10 in FIG. 22A.

Referring to FIG. 23, the semiconductor device 20 includes multiple metal silicide layers 142 respectively disposed on the doped regions 140 and 141. The metal silicide layers 142 can be formed using the process or method described with reference to FIG. 10C. The metal silicide layer 142 is disposed between the capacitor structure 195 and each of the doped regions 140 and 141. The metal silicide layers 142 can improve electrical conductivity of the doped regions 140 electrically connected to the capacitor structure 195.

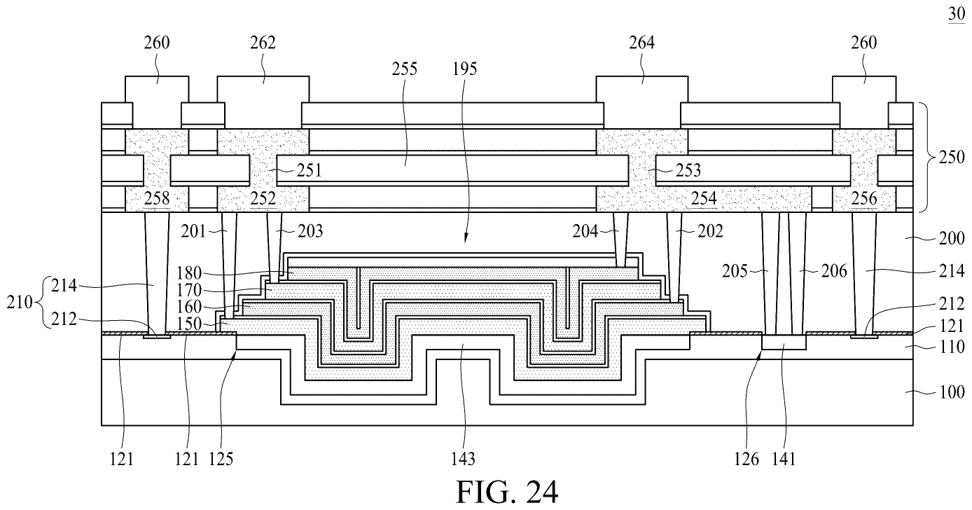

Referring to FIG. 24, the semiconductor device 30 includes a single doped region 143 below the capacitor structure 195. The doped region 143 is similar to the doped region 140 except that doped region 143 has a greater length and area. The doped region 143 may be formed by an implantation operation performed on the doped layer 110 shown in FIG. 8H. The doped region 143 extends from the isolation member 121 adjacent to the doped region 212 to the isolation member 121 adjacent to the doped region 141.

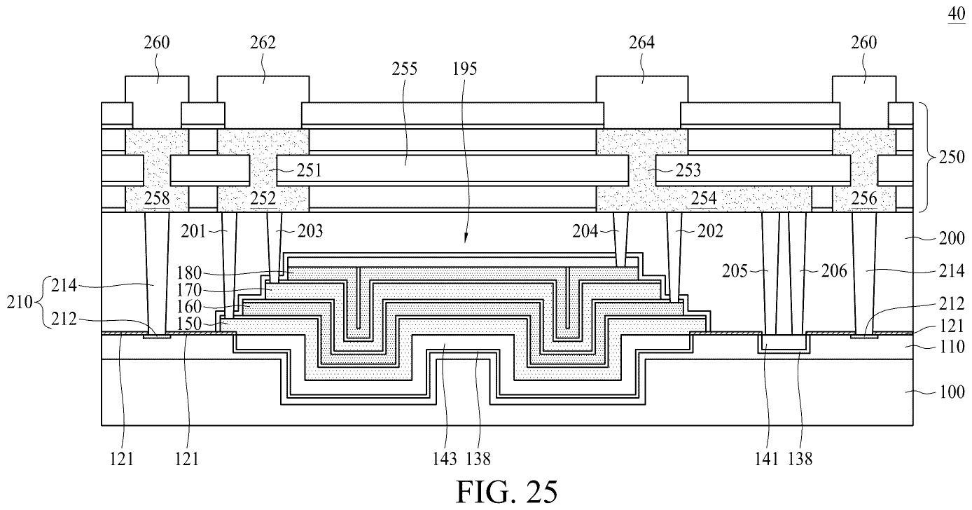

Referring to FIG. 25, the semiconductor device 40 is similar to the semiconductor device 30 in FIG. 24. The semiconductor device 40 includes multiple lightly-doped regions 138 respectively surrounding the doped regions 143 and 141. In some embodiments, the lightly-doped regions 138 are N type. P-N junctions may be formed between the P-type doped layer 110 and the N-type lightly-doped regions 138.

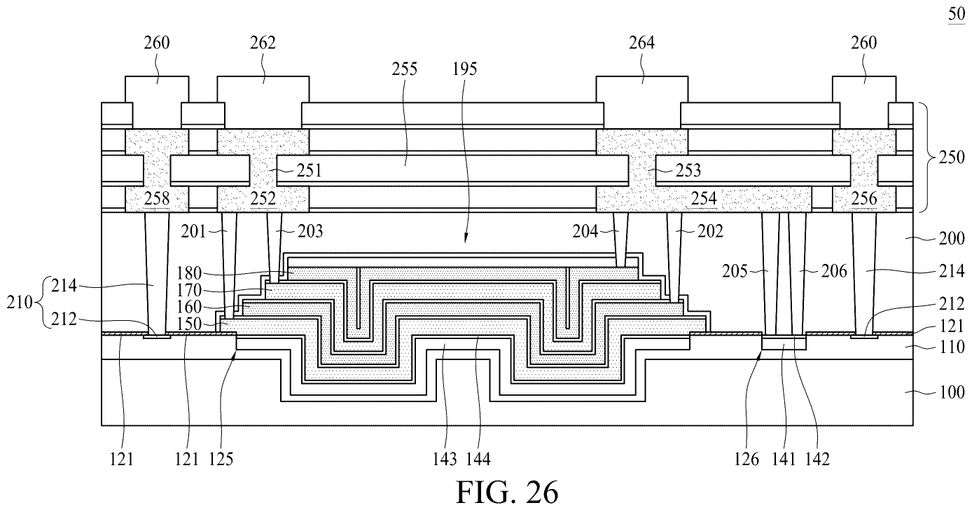

Referring to FIG. 26, the semiconductor device 50 is similar to the semiconductor device 20 in FIG. 23. The semiconductor device 50 includes a metal silicide layer 144 formed on the doped region 143 and the metal silicide layer 142 formed on the doped region 141. The metal silicide layer 144 is disposed between the capacitor structure 195 and the doped region 143. The metal silicide layer 144 can improve electrical conductivity of the doped region 143 electrically connected to the capacitor structure 195.

One aspect of the present disclosure provides a method of manufacturing a semiconductor device. The method includes: forming a plurality of trenches in a substrate; forming a doped layer of a first conductivity type in the substrate; forming a plurality of isolation members over the doped layer; forming a plurality of first doped regions of a second conductivity type at upper portions of the doped layer. The plurality of first doped regions and the plurality of isolation members are alternately arranged; and conformally forming a stacked structure in the plurality of trenches. The stacked structure includes a plurality of layers stacked in an order of a first conductive layer, a first dielectric layer, a second conductive layer, a second dielectric layer, a third conductive layer, a third dielectric layer and a fourth conductive layer. The first conductive layer is in contact with and electrically coupled to the plurality of first doped regions.

One aspect of the present disclosure provides another method of manufacturing a semiconductor device. The method includes: providing a substrate of a first conductivity type, the substrate including a device region and a peripheral region adjacent to the device region; forming a trench in the substrate; forming a doped layer of the first conductivity type in the substrate; forming first and second isolation members over the doped layer in the device region; respectively forming a first diode and a second diode by forming a first doped region and a second doped region of a second conductivity type, wherein the first diode is in the device region and the second diode is in the peripheral region; conformally forming a stacked structure in the trench, wherein the stacked structure includes a first electrode, a second electrode, a third electrode and a fourth electrode separated by dielectric layers and sequentially stacked from bottom to top, wherein the first electrode is electrically coupled to the first diode; respectively forming first, second, third, fourth and fifth contacts on the first electrode, the second electrode, the third electrode, the fourth electrode and the second diode; and forming an interconnect structure over the stacked structure.

Another aspect of the present disclosure provides a semiconductor device. The semiconductor device includes: a substrate; a doped layer of a first conductivity type in the substrate; a plurality of isolation members, disposed over the doped layer; a plurality of doped regions of a second conductivity type, disposed over the doped layer, wherein the plurality of doped regions and the plurality of isolation members are alternately arranged with each other; and a capacitor structure disposed over the plurality of isolation members, wherein a bottom of the capacitor structure is in direct contact and coupled to each of the plurality of doped regions.

The foregoing outlines structures of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of manufacturing a semiconductor device, comprising:
forming a plurality of trenches in a substrate;
forming a doped layer of a first conductivity type in the substrate;
forming a plurality of isolation members over the doped layer;
forming a plurality of first doped regions of a second conductivity type at upper portions of the doped layer, wherein the plurality of first doped regions and the plurality of isolation members are alternately arranged; and
conformally forming a stacked structure in the plurality of trenches, wherein the stacked structure includes a plurality of layers stacked in an order of a first conductive layer, a first dielectric layer, a second conductive layer, a second dielectric layer, a third conductive layer, a third dielectric layer and a fourth conductive layer, wherein the first conductive layer is in contact with and electrically coupled to the plurality of first doped regions.

2. The method of claim 1, further comprising:
respectively forming first, second, third and fourth contacts on the first, second, third and fourth conductive layers; and
forming an interconnect structure including a first metal line and a second metal line over the stacked structure, wherein
the first contact is electrically connected to the third contact by the first metal line, and
the second contact is electrically connected to the fourth contact by the second metal line.

3. The method of claim 1, wherein the plurality of first doped regions and the plurality of trenches are alternately arranged.

4. The method of claim 1, further comprising, prior to the forming of the first, second, third and fourth contacts:
forming a capping layer over the fourth conductive layer; and
sequentially patterning the fourth conductive layer, the third dielectric layer, the third conductive layer, the second dielectric layer, the second conductive layer, the first dielectric layer and the first conductive layer such that the stacked structure has a stepped profile.

5. The method of claim 1, further comprising forming a metal silicide layer on each of the plurality of first doped regions.

6. The method of claim 1, wherein the first conductivity type is P type and the second conductivity type is N type.

7. The method of claim 6, further comprising forming a plurality of lightly-doped regions of the second conductivity type, wherein each of the plurality of lightly-doped regions surrounds one of the plurality of first doped regions, wherein a dopant concentration of each of the plurality of lightly-doped regions is less than a dopant concentration of each of the plurality of first doped regions.

8. The method of claim 2, further comprising:
forming a second doped region of the second conductivity type at an upper portion of the doped layer, wherein the fourth doped region is separated from the stacked structure; and
forming a fifth contact on the second doped region to electrically connect the second doped region to the second metal line.

9. The method of claim 8, further comprising forming a grounding structure on the doped layer, wherein the grounding structure includes:
a third doped region of the first conductivity type, surrounding the stacked structure and the second doped region from a top view; and
a sixth contact, electrically connecting the third doped region to the interconnect structure.

10. A method of manufacturing a semiconductor device, comprising:
providing a substrate of a first conductivity type, the substrate including a device region and a peripheral region adjacent to the device region;
forming a trench in the substrate;
forming a doped layer of the first conductivity type in the substrate;
forming first and second isolation members over the doped layer in the device region;
respectively forming a first diode and a second diode by forming a first doped region and a second doped region of a second conductivity type, wherein the first diode is in the device region and the second diode is in the peripheral region;
conformally forming a stacked structure in the trench, wherein the stacked structure includes a first electrode, a second electrode, a third electrode and a fourth electrode separated by dielectric layers and sequentially stacked from bottom to top, wherein the first electrode is electrically coupled to the first diode;
respectively forming first, second, third, fourth and fifth contacts on the first electrode, the second electrode, the third electrode, the fourth electrode and the second diode; and
forming an interconnect structure over the stacked structure.

11. The method of claim 10, wherein
the interconnect structure includes first and second conductive lines separated from each other,
the first and third contacts are electrically connected to the first conductive line, and
the second, fourth and fifth contacts are electrically connected to the second conductive line.

12. The method of claim 11, further comprising forming a grounding structure in the peripheral region and surrounding the stacked structure from a top perspective, wherein the grounding structure includes:
a third doped region of the first conductivity type disposed on or within the doped layer; and
a sixth contact electrically connecting the third doped region to a third conductive line in the interconnect structure.

13. The method of claim 10, wherein the first doped region extends from the first isolation member to the second isolation member.

14. A semiconductor device, comprising:
a substrate;
a doped layer of a first conductivity type in the substrate;
a plurality of isolation members, disposed over the doped layer;
a plurality of doped regions of a second conductivity type, disposed over the doped layer, wherein the plurality of doped regions and the plurality of isolation members are alternately arranged with each other; and
a capacitor structure disposed over the plurality of isolation members, wherein a bottom of the capacitor structure is in direct contact and coupled to each of the plurality of doped regions.

15. The semiconductor device of claim 14, further comprising a plurality of lightly-doped regions of the second conductivity type disposed in the doped layer, wherein each of the doped regions is surrounded by one of the plurality of lightly-doped regions, and a dopant concentration of the lightly-doped region is less than a dopant concentration of the doped regions.

16. The semiconductor device of claim 14, further comprising a metal silicide layer disposed between the capacitor structure and each of the plurality of doped regions.

17. The semiconductor device of claim 14, wherein the capacitor structure includes a plurality of conductive layers and a plurality of dielectric layers alternately stacked, wherein a bottommost conductive layer of the plurality of conductive layers is in direct contact with the plurality of doped regions.

18. The semiconductor device of claim 17, wherein the bottommost conductive layer is separated from the doped layer by one or more of the plurality of isolation members.

19. The semiconductor device of claim 14, further comprising:
a first contact, disposed on the first conductive layer;
a second contact, disposed on the second conductive layer;
a third contact, disposed on the third conductive layer;
a fourth contact, disposed on the fourth conductive layer; and
an interconnect structure, including a first metal line and a second metal line separated from each other and disposed over the capacitor structure, wherein
the first contact is electrically connected to the third contact by the first metal line, and
the second contact is electrically connected to the fourth contact by the second metal line.

20. The semiconductor device of claim 14, further comprising:
a grounding structure disposed on the substrate, wherein the grounding structure includes a doped region of the first conductivity type disposed on or within the doped layer and surrounding the capacitor structure from a top view; and
a fifth contact, electrically connecting the doped region of the first conductivity type to the interconnect structure.
